(19) United States
(12) Patent Application Publication
(10) Pub. No.: US 2025/0098511 A1
(43) Pub. Date: Mar. 20, 2025

(54) DISPLAY DEVICE AND METHOD OF MANUFACTURING THE SAME

(71) Applicant: Samsung Display Co., Ltd., Yongin-Si (KR)

(72) Inventor: AHNHO JEE, Yongin-si (KR)

(21) Appl. No.: 18/752,808

(22) Filed: Jun. 25, 2024

(30) Foreign Application Priority Data
Sep. 15, 2023 (KR) 10-2023-0123355

(51) Int. Cl. H10K 71/50; H10K 59/12; H10K 59/127; H10K 71/00; H10K 71/60

(52) U.S. Cl. CPC H10K 71/50; H10K 59/1201; H10K 59/1275; H10K 71/60; H10K 71/621

(57) ABSTRACT

Disclosed is a method of manufacturing a display device, the method including manufacturing an electronic component and attaching the electronic component to a display panel using a conductive adhesive member. The manufacturing of the electronic component includes providing a substrate and a conductive layer disposed on the substrate, a primary etching of the conductive layer to form a preliminary bump electrode, and a secondary etching of the preliminary bump electrode to form a bump electrode.

### CROSS-REFERENCE TO RELATED APPLICATIONS

This application claims priority under 35 U.S.C. § 119 to Korean Patent Application No. 10-2023-0123355 filed on Sep. 15, 2023, in the Korean Intellectual Property Office, the disclosure of which is incorporated by reference herein in its entireties.

### BACKGROUND

Embodiments described in the present disclosure relate to a display device and more particularly to a display device in which a display panel and an electronic component are more reliably bonded and further relate to a method of manufacturing the same.

A display device generally includes a display area that is activated by an electrical signal. The display device may detect input applied from an external unit to the display area, at the same time, the display area displays various images and thus provides information to a user. The display device may include a display panel and a circuit board. The display panel may be connected to a main board through the circuit board. A driving circuit chip may be mounted on the display panel.

### SUMMARY

Embodiments of the present disclosure may provide a display device having improved bonding reliability, and a method of manufacturing the same.

According to an embodiment, a method of manufacturing a display device includes manufacturing an electronic component, and attaching the electronic component to a display panel using a conductive adhesive member. The manufacturing of the electronic component may include providing a substrate and a conductive layer disposed on the substrate, primary etching the conductive layer to form a preliminary bump electrode, and secondarily etching the preliminary bump electrode to form a bump electrode.

The preliminary bump electrode may include a protrusion protruding in a side direction, and the protrusion may be removed in the secondarily etching of the preliminary bump electrode.

The primary etching of the conductive layer may be performed during a first etching time, the secondarily etching of the preliminary bump electrode may be performed during a second etching time, and the second etching time may be shorter than the first etching time.

The manufacturing of the electronic component may further include forming a first photoresist pattern on the conductive layer using a half-tone mask after the providing of the substrate and the conductive layer and before the primary etching of the conductive layer.

The method may further include removing a portion of the first photoresist pattern to form a second photoresist pattern after the primary etching of the conductive layer and before the secondary etching of the preliminary bump electrode, and removing the second photoresist pattern after the secondary etching of the preliminary bump electrode.

The first photoresist pattern may include a first pattern part and a second pattern part that is thinner than the first pattern part, and in the removing of the portion of the first photoresist pattern, the second pattern part may be removed, and an upper portion of the preliminary bump electrode may be exposed.

The manufacturing of the electronic component may further include forming a photoresist pattern using a mask in which an exposure opening is defined after the providing of the substrate and the conductive layer and before the primary etching of the conductive layer, and removing the photoresist pattern after the secondary etching of the preliminary bump electrode.

In both the primary etching of the conductive layer and the secondary etching of the preliminary bump electrode, the photoresist pattern may be used as the mask.

The manufacturing of the electronic component may further include forming a first photoresist pattern using a first mask in which a first exposure opening is defined after the providing of the substrate and the conductive layer and before the primary etching of the conductive layer, and forming a second photoresist pattern using a second mask in which a second exposure opening is defined after the primary etching of the conductive layer and before the secondary etching of the preliminary bump electrode, and a width of the second photoresist pattern may be smaller than a width of the first photoresist pattern.

The bump electrode may not include a portion having a width that is widened in a direction from a lower surface to an upper surface thereof.

In the attaching of the electronic component to the display panel, the conductive adhesive member may be in contact with an upper surface and a side surface of the bump electrode.

A side surface of the bump electrode may include a first side surface portion extending from a lower surface of the bump electrode, and a second side surface portion that extends from the first side surface portion to an upper surface of the bump electrode and defines a bend point with the first side surface portion.

A side surface of the bump electrode may have a substantially constant inclination.

The electronic component may be any one of a flexible circuit board and a driving circuit chip.

According to an embodiment, a display device includes a display panel including a base layer and a display pad disposed on the base layer, an electronic component disposed on the display panel and including a substrate and a bump electrode disposed under the substrate, and a conductive adhesive member that electrically connects the display panel and the electronic component, wherein a side surface of the bump electrode includes a first side surface portion extending from a lower surface of the bump electrode, and a second side surface portion that extends from the first side surface portion to an upper surface of the bump electrode and defines a bend point with the first side surface portion, and the conductive adhesive member may be in contact with the first side surface portion and the second side surface portion.

An inclination of the second side surface portion may be smaller than an inclination of the first side surface portion.

The second side surface portion may define a recessed portion.

The bump electrode may not include a portion having a width that is widened in a direction from the lower surface to the upper surface thereof.

The conductive adhesive member may include an adhesive resin and conductive balls dispersed in the adhesive resin.

The electronic component may be any one of a flexible circuit board and a driving circuit chip.

### BRIEF DESCRIPTION OF THE FIGURES

The above and other objects and features of the present disclosure will become apparent by describing in detail embodiments thereof with reference to the accompanying drawings.

FIG. 1 is a perspective view of a display device according to an embodiment

of the present disclosure.

FIGS. 2A and 2B are exploded perspective views of a display device according to an embodiment of the present disclosure.

FIG. 3 is a cross-sectional view of a display module according to an embodiment of the present disclosure.

FIG. 4 is a plan view of a display panel according to an embodiment of the present disclosure.

FIG. 5 is a cross-sectional view of a display panel according to an embodiment of the present disclosure.

FIG. 6 is an enlarged exploded view of a portion of a display device according to an embodiment of the present disclosure.

FIG. 7 is an enlarged cross-sectional view of a portion of a display device according to an embodiment of the present disclosure.

FIG. 8 is an enlarged cross-sectional view of a portion of a display device according to an embodiment of the present disclosure.

FIG. 9 is an enlarged cross-sectional view of a portion of a display device according to an embodiment of the present disclosure.

FIG. 10 is an enlarged cross-sectional view of a portion of a display device according to an embodiment of the present disclosure.

FIG. 11 is a plan view illustrating a flexible circuit board according to an embodiment of the present disclosure.

FIG. 12 is a flowchart illustrating a method of manufacturing a display device according to an embodiment of the present disclosure.

FIG. 13 is a flowchart illustrating some operations of a method of manufacturing a display device according to an embodiment of the present disclosure.

FIGS. 14A, 14B, 14C, 14D, 14E, 14F, 14G, 14H, 14I, and 14J are cross-sectional views sequentially illustrating some of the structures formed by a method of manufacturing the display device according to an embodiment of the present disclosure.

FIGS. 15A, 15B, and 15C are cross-sectional views of some structures formed by a method of manufacturing a display device according to an embodiment of the present disclosure.

FIG. 16 is a flowchart illustrating some operations of a method of manufacturing a display device according to an embodiment of the present disclosure.

FIGS. 17A, 17B, 17C, and 17D are cross-sectional views of some structures formed by a method of manufacturing a display device according to an embodiment of the present disclosure.

FIG. 18 is a flowchart illustrating some operations of a method of manufacturing a display device according to an embodiment of the present disclosure.

FIGS. 19A, 19B, 19C, and 19D are cross-sectional views of some structures formed by a method of manufacturing the display device according to an embodiment of the present disclosure.

FIG. 20 is an enlarged cross-sectional view of a portion of a display device according to a comparative example.

### DETAILED DESCRIPTION

In the present specification, a first component (or an area, a layer, a part, a portion, etc.) referred to as being “disposed on”, “connected with” or “coupled to” a second component means that the first component is directly disposed on/connected with/coupled to the second component or means that a third component is interposed therebetween.

The term “and/or” as used herein includes all combinations of one or more components that may be defined by associated components.

Although the terms “first”, “second”, etc. may be used to describe various components, the components should not be limited by these terms. The terms are only used to distinguish one component from another component. For example, without departing from the right scope of the present disclosure, a first component may be referred to as a second component, and similarly, the second component may be also referred to as the first component. Singular expressions include plural expressions unless clearly otherwise indicated in the context.

Also, the terms “under”, “below”, “on”, “above”, etc. are used to describe the correlation or relationship of components illustrated in drawings. The terms that are relative in concept are described based on a direction illustrated in drawings.

It will be understood that the terms “include”, “comprise”, “have”, etc. specify the presence of features, numbers, steps, operations, elements, or components, described in the specification, or a combination thereof, and do not exclude the presence or additional possibility of one or more other features, numbers, steps, operations, elements, or components or a combination thereof.

Unless otherwise defined, all terms (including technical terms and scientific terms) used in the present specification have the same meaning as commonly understood by those skilled in the art to which the present disclosure belongs. Furthermore, terms such as terms defined in the dictionaries commonly used should be interpreted as having a meaning consistent with the meaning in the context of the related technology and should not be interpreted as having overly ideal or overly formal meanings unless explicitly defined herein.

Hereinafter, an embodiment of the present disclosure will be described with reference to the accompanying drawings. The same reference numerals or characters used to identify components in multiple drawings refer to the similar or identical components. Further, in the drawings, the thickness, the ratio, and the dimension of components may be exaggerated or otherwise altered for effective description of technical contents.

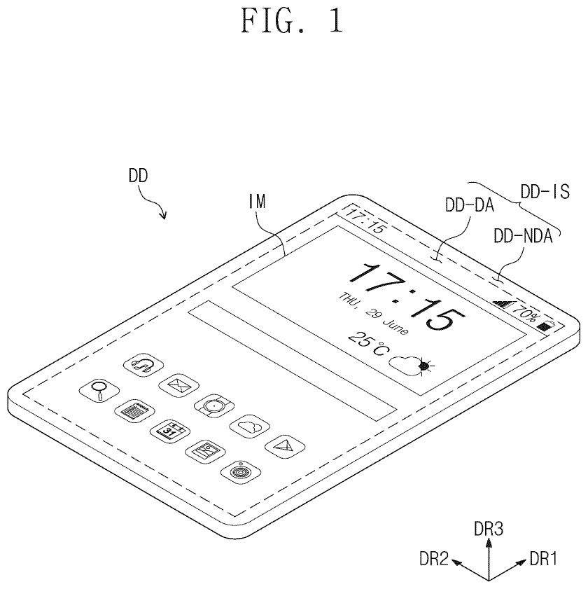

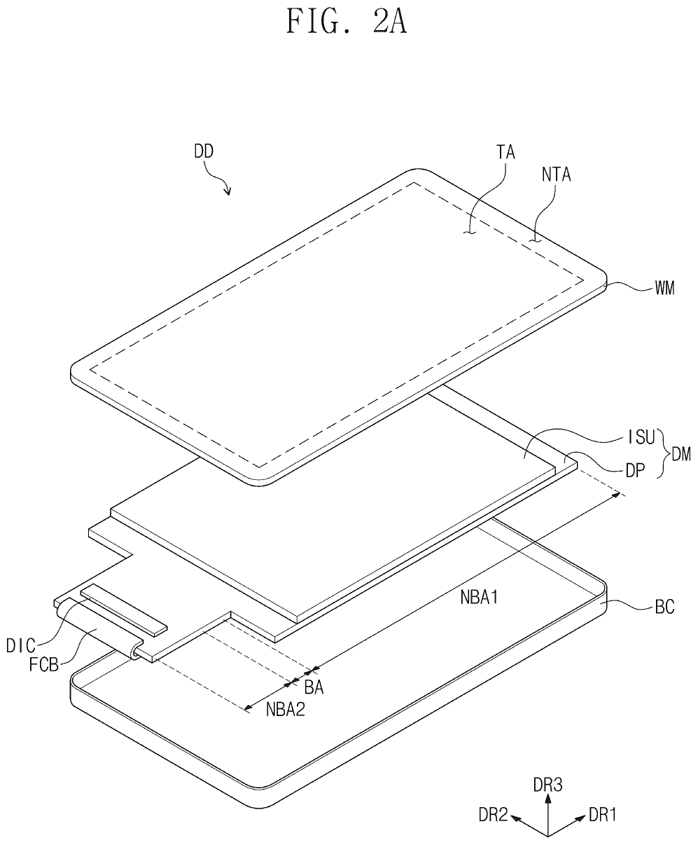

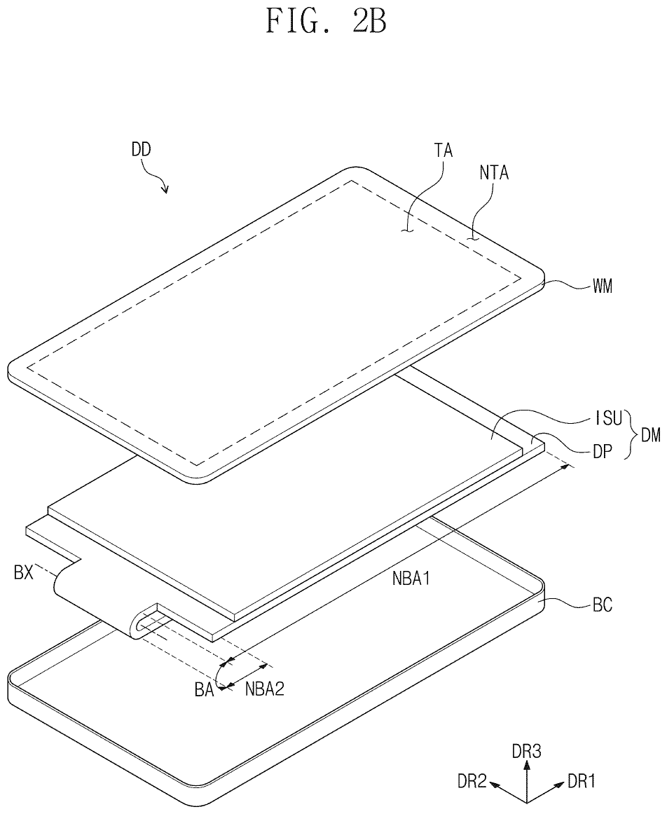

FIG. 1 is a perspective view of a display device DD according to an embodiment of the present disclosure. FIGS. 2A and 2B are exploded perspective views of the display device DD according to an embodiment of the present disclosure. FIG. 2A particularly illustrates the display device DD in a state in which a bending area BA of a display panel DP is unbent, and FIG. 2B illustrates a state in which the bending area BA of the display panel DP is bent.

FIG. 1 illustrates an example in which the display device DD is a mobile phone terminal. The display device DD according to the present disclosure may more generally be applied to other applications including small and medium-sized electronic devices such as tablets, vehicle navigation systems, game consoles, and smart watches as well as large-sized electronic devices such as televisions and monitors.

The display device DD may have a rectangular shape with long sides extending in a first direction DR1 and short sides extending in a second direction DR2 that is at an angle to the first direction DR1. However, the present disclosure is not limited thereto, and the display device DD may have various planar shapes such as a circle and a polygon.

The display device DD also has a thickness extending in a third direction DR3. Hereinafter, the third direction DR3 is defined to be a direction substantially perpendicular to a plane defined by the first direction DRI and the second direction DR2. In the specification, the wording “when viewed on a plane” means when viewed from the third direction DR3.

The display device DD may be rigid or flexible. The word “flexible” applied to a structure means that the structure may be bent, which includes both a structure that can be completely folded and a structure that may be bent by several nanometers. For example, the flexible display device DD may include a curved electronic device, a rollable electronic device, or a foldable electronic device.

The display device DD may display an image IM through a display surface DD-IS. Icon images are illustrated in FIG. 1 as examples of the image IM. The display surface DD-IS may be parallel to the plane defined by the first direction DR1 and the second direction DR2.

The display surface DD-IS may include a display area DD-DA that displays the image IM and a non-display area DD-NDA adjacent to the display area DD-DA. The non-display area DD-NDA may be an area that does not display an image. The non-display area may surround the display area DD-DA. However, the present disclosure is not limited thereto, and the non-display area DD-NDA may be adjacent to one side of the display area DD-DA or may be omitted.

Referring to FIGS. 2A and 2B, the display device DD may include a window WM, a display module DM, and a storage member or back case BC.

The window WM may be disposed on the display module DM and may transmit light from an image that the display module DM provides. The window WM may include a transmissive area TA and a non-transmissive area NTA. The transmissive area TA may overlap the display area DD-DA illustrated in FIG. 1 and have a shape corresponding to the display area DD-DA. Although not illustrated, the window WM may include a base layer and functional layers arranged on the base layer. The functional layers may include a protective layer, a fingerprint preventing layer, and the like. The base layer of the window WM may be made of glass, sapphire, or plastic. The base layer of the window WM may include an optically transparent insulating material. For example, the base layer of the window WM may include a glass or plastic film or may include a glass substrate and a plastic film bonded by an adhesive.

The non-transmissive area NTA may overlap the non-display area DD-NDA illustrated in FIG. 1 and have a shape corresponding to the non-display area DD-NDA. The non-transmissive area NTA may be an area having relatively low light transmittance compared to the transmissive area TA. The non-transmissive area NTA may be defined by a bezel pattern in or on a portion of the base layer of the window WM, and an area in which the bezel pattern is not disposed may be defined as the transmissive area TA. However, the present disclosure is not limited thereto, and the non-transmissive area NTA may be omitted.

Although not illustrated, a reflection preventing layer may be disposed between the window WM and the display module DM. The reflection preventing layer may reduce reflectance of an external light beam incident on the display module DM from the outside of the display device DD. The reflection preventing layer may include color filters. The color filters may have a predetermined arrangement. For example, the color filters may be arranged in consideration of light emitting colors of pixels included in a display panel DP, which will be described below. Further, the reflection preventing layer may further include a black matrix adjacent to the color filters.

According to an embodiment of the present disclosure, the display module DM may include the display panel DP and an input sensor ISU.

The display panel DP may be one of a liquid crystal display panel, an electrophoretic display panel, a microelectromechanical system display panel, an electrowetting display panel, an organic light emitting display panel, an inorganic light emitting display panel, and a quantum dot light emitting display panel. However, the present disclosure is not limited thereto. Hereinafter, the example in which the display panel DP is an organic light emitting display panel will be described.

The input sensor ISU may include any one of a capacitive sensor, an optical sensor, an ultrasonic sensor, and an electromagnetic induction sensor, which may be capable of sensing a touch on the outer surface of the window WM. The input sensor ISU may be formed on the display panel DP through a continuous process or may be separately manufactured and then attached to an upper portion of the display panel DP through an adhesive layer, and the present disclosure is not limited to one embodiment of the input sensor ISU.

The display module DM may further include a driving circuit chip DIC disposed on the display panel DP. The display module DM may further include a circuit board FCB disposed on the display panel DP. In an embodiment, the circuit board FCB may be a flexible circuit board. Hereinafter, the circuit board FCB may be described as the flexible circuit board FCB, but the present disclosure is not limited thereto. For example, the circuit board FCB may be rigid. The circuit board FCB may electrically connect the display panel DP and a main circuit board.

The driving circuit chip DIC may include driving elements, for example, a data driving circuit, for driving pixels of the display panel DP. Although FIG. 2A illustrates a structure in which the driving circuit chip DIC is mounted on the display panel DP, the present disclosure is not limited thereto. For example, the driving circuit chip DIC may be mounted on the flexible circuit board FCB. In an embodiment, the driving circuit chip DIC directly mounted on the display panel DP and the flexible circuit board FCB may be collectively referred to as electronic components. A bonding structure between the display panel DP and the flexible circuit board FCB, which will be described below, may be equally applied to other electronic components such as the driving circuit chip DIC.

The display panel DP may include the bending area BA and a first non-bending area NBA1 and a second non-bending area NBA2 spaced apart from each other in the first direction DRI with the bending area BA interposed therebetween.

The bending area BA may be defined as an area in which the display panel DP may be bent about a virtual bending axis BX extending in the second direction DR2. The first non-bending area NBA1 may include an area overlapping the transmissive area TA, and the second non-bending area NBA2 may be an area to which the flexible circuit board FCB is connected. When the bending area BA is bent about the bending axis BX, the flexible circuit board FCB and the driving circuit chip DIC may be face toward a rear surface of the display device DD and thus may be arranged under the rear surface of the display panel DP. Although not illustrated, additional components may be arranged to compensate for a step difference between the flexible circuit board FCB and the rear surface of the display panel DP, which is caused by the bending area BA.

According to an embodiment, a width of the first non-bending area NBA1 in the second direction DR2 may be greater than widths of the bending area BA and the second non-bending area NBA2. For example, the width of the bending area BA in the second direction DR2 may be provided in a shape that becomes narrower from the first non-bending area NBA1 to the second non-bending area NBA2. The present disclosure is not limited to an embodiment in which the second non-bending area NBA2 is narrower than the first non-bending area NBA1.

As illustrated in FIG. 2B, a portion of the display panel DP is bent, and the flexible circuit board FCB electrically bonded to the display panel DP may be disposed on the rear surface of the display panel DP.

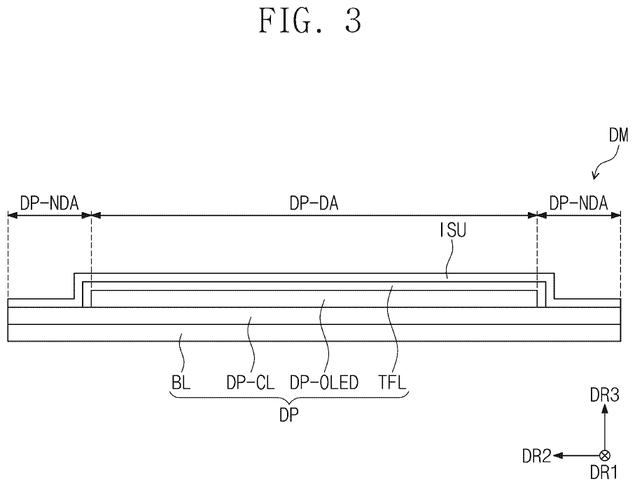

The storage member BC may accommodate the display module DM and may be coupled to the window WM. The flexible circuit board FCB may be disposed at one end of the display panel DP and may be electrically connected to a circuit element layer DP-CL, which will be described in FIG. 3. Although not illustrated, the display device DD may further include a main board, electronic modules mounted on the main board, a camera module, a power module, and the like.

FIG. 3 is a cross-sectional view of the display module DM according to an embodiment including the display panel DP and the input sensor ISU. Referring to FIG. 3, the display panel DP may include a base layer BL, the circuit element layer DP-CL disposed on the base layer BL, a display element layer DP-OLED, and an upper insulating layer TFL. The input sensor ISU may be disposed on the upper insulating layer TFL.

The display panel DP may include a display area DP-DA and a non-display area DP-NDA. The display area DP-DA of the display panel DP may correspond to the display area DD-DA illustrated in FIG. 1 or the transmissive area TA illustrated in FIG. 2A, and the non-display area DP-NDA may correspond to the non-display area DD-NDA illustrated in FIG. 1 or the non-transmissive area NTA illustrated in FIG. 2A.

The base layer BL may include at least one plastic film. The base layer BL may be a flexible substrate and may include a plastic substrate, a glass substrate, a metal substrate, or an organic/inorganic composite material substrate.

The circuit element layer DP-CL may include at least one intermediate insulating layer and at least one conductive or semiconductor layer. The intermediate insulating layer may include at least one intermediate inorganic layer and at least one intermediate organic layer. The conductive or semiconductor layer may include or form signal lines, a driving circuit of a pixel, and the like.

The display element layer DP-OLED may include organic light emitting diodes of a plurality of pixels. The display element layer DP-OLED may further include an organic layer such as a pixel defining film.

The upper insulating layer TFL may seal the display element layer DP-OLED. The upper insulating layer TFL may be disposed on the display element layer DP-OLED. The upper insulating layer TFL may overlap the display area DP-DA and the non-display area DP-NDA. The upper insulating layer TFL may overlap at least a portion of the non-display area DP-NDA. For example, the upper insulating layer TFL may include a thin film encapsulation layer. The thin film encapsulation layer may include a laminated structure of an inorganic layer, an organic layer, and an inorganic layer. The upper insulating layer TFL may protect the display element layer DP-OLED from foreign substances such as moisture, oxygen, and dust particles. However, the present disclosure is not limited thereto, and the upper insulating layer TFL may further include an additional insulating layer in addition to the thin film encapsulation layer. For example, the upper insulating layer TFL may further include an optical insulating layer for controlling a refractive index.

In an embodiment of the present disclosure, an encapsulation substrate may be provided instead of the upper insulating layer TFL. In this case, the encapsulation substrate may face the base layer BL, and the circuit element layer DP-CL and the display element layer DP-OLED may be arranged between the encapsulation substrate and the base layer BL.

The input sensor ISU may be directly disposed on the display panel DP. (Herein, a statement that “component A is directly disposed on component B” means that no separate layer is disposed between component A and component B.) In an embodiment, the input sensor ISU together with the display panel DP may be manufactured by a continuous process. However, embodiments of the present disclosure are not limited thereto, and the input sensor ISU may be provided as a separate panel and coupled to the display panel DP through an adhesive layer. In some embodiments, the input sensor ISU may be omitted.

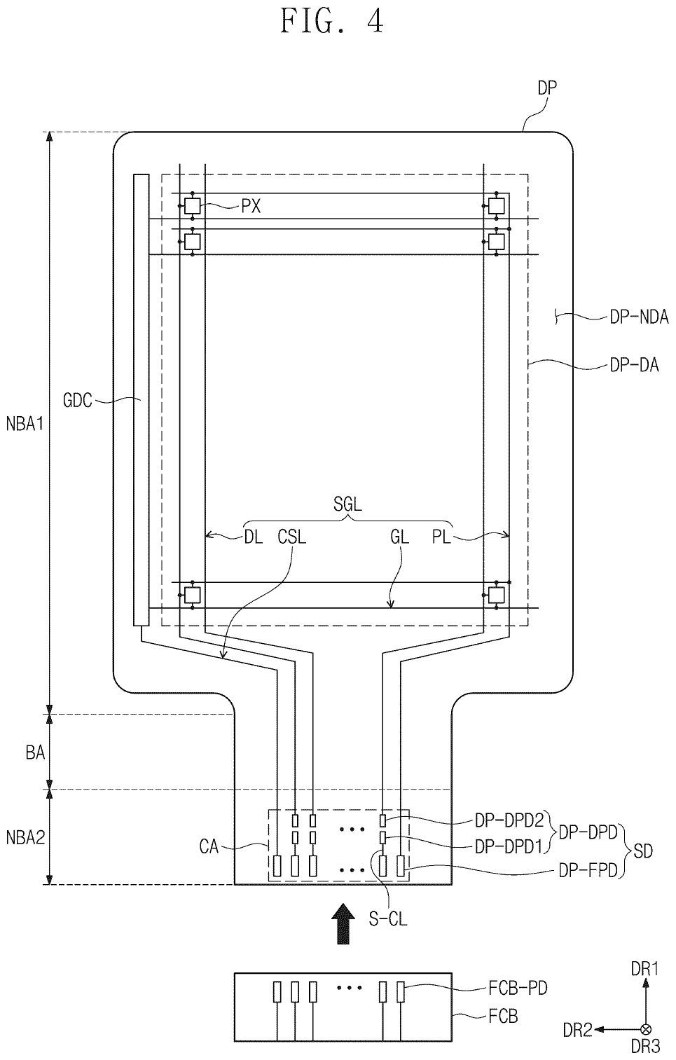

FIG. 4 is a plan view of the display panel DP according to an embodiment of the present disclosure. Referring to FIG. 4, the display panel DP may include a plurality of pixels PX, a gate driving circuit GDC, a plurality of signal lines SGL, and a plurality of display pads SD.

The pixels PX may be arranged in the display area DP-DA. Each of the pixels PX may include an organic light emitting diode and a pixel driving circuit connected to the organic light emitting diode.

The gate driving circuit GDC and the signal lines SGL may be included in the circuit element layer DP-CL illustrated in FIG. 3. The gate driving circuit GDC may sequentially output gate signals to a plurality of gate lines GL. The gate driving circuit GDC may include a plurality of thin film transistors formed through the same process that forms the pixel driving circuits of the pixels PX. For example, a low temperature polycrystaline silicon (LTPS) process or a low temperature polycrystalline oxide (LTPO) process may form the gate driving circuit GDC and the pixel driving circuits. The display panel DP may further include another driving circuit (not shown) that provides light emitting control signals to the pixels PX.

The signal lines SGL may include the gate lines GL, data lines DL, a power line PL, and a control signal line CSL. Each of the gate lines GL may extend in the second direction DR2 and may be connected to a set, e.g., row, of corresponding pixel PX among the pixels PX, and each of the data lines DL may extend in the first direction DR1 and may be connected to a set, e.g., column, of corresponding pixel PX among the pixels PX. The gate lines GL may be connected to the gate driving circuit GDC, and the data lines DL may be connected to the driving circuit chip DIC via the bending area BA. The power line PL may extend in the first direction DR1 and the second direction DR2 and may be connected to the pixels PX. A portion, which extends in the first direction DR1, of the power line PL may extend from the first non-bending area NBA1 to the second non-bending area NBA2 via the bending area BA. The power line PL may provide a high power voltage (e.g., ELVDD) to the pixels PX. The control signal line CSL may be connected to the gate driving circuit GDC and may extend from the first non-bending area NBA1 to the second non-bending area NBA2 via the bending area BA.

The display panel DP may include the plurality of display pads SD. The plurality of display pads SD may be spaced a predetermined distance from each other. The plurality of display pads SD according to an embodiment may be arranged in a connection area CA of the second non-bending area NBA2. The connection area CA may be defined as an area of the second non-bending area NBA2, in which the display pads SD are arranged. The driving circuit chip DIC (see FIG. 2A) and the flexible circuit board FCB may be attached to the connection area CA.

The display pads SD may include first pads DP-DPD and second pads DP-FPD. The first pads DP-DPD may be arranged to overlap the connection area CA. The driving circuit chip DIC (see FIG. 2A) may be mounted on the second non-bending area NBA2. The first pads DP-DPD may be electrically connected to the driving circuit chip DIC (see FIG. 2A) and may transmit electrical signals received from the driving circuit chip DIC (see FIG. 2A) to the data lines DL. The driving circuit chip DIC (see FIG. 2A) may generate an analog voltage corresponding to a greyscale value of an image signal.

The first pads DP-DPD may be arranged in rows extending along the second direction DR2 and separated from each other in the first direction DR1. The first pads DP-DPD may include first row pads DP-DPD1 and second row pads DP-DPD2 spaced apart from the first row pads DP-DPD1 in the first direction DRI and arranged in the second direction DR2. The second row pads DP-DPD2 may be input pads that receive signals from the driving circuit chip DIC (see FIG. 2A), and the first row pads DP-DPD1 may be output pads that output signals to the driving circuit chip DIC (see FIG. 2A). However, the present disclosure is not limited thereto, and the first pads DP-DPD may be arranged in one row or in three or more rows in the second direction DR2.

The second pads DP-FPD may be arranged to overlap the connection area CA. The first pads DP-DPD and the second pads DP-FPD may be connected to each other through bridge signal lines S-CL. Like the first pads DP-DPD, the second pads DP-FPD may also be arranged in the second direction DR2. The second pads DP-FPD may be arranged to be spaced apart from each other in the second direction DR2.

The flexible circuit board FCB may include substrate bump electrodes FCB-PD electrically connected to the display panel DP. The substrate bump electrodes FCB-PD included in the flexible circuit board FCB may have an arrangement that matches an arrangement of the second pads DP-FPD. For example, when the second pads DP-FPD are arranged in row extending along the second direction DR2, the substrate bump electrodes FCB-PD may be also arranged in a row extending along the second direction DR2. However, the present disclosure is not limited any specific arrangement.

The second pads DP-FPD may be electrically connected to the substrate bump electrodes FCB-PD included in the flexible circuit board FCB and transmit electrical signals received from the flexible circuit board FCB to the first pads DP-DPD.

Although not illustrated, the flexible circuit board FCB may include a timing control circuit that controls operation of the display panel DP. The timing control circuit may be mounted on the flexible circuit board FCB in the form of an integrated chip. Also, although not illustrated, the flexible circuit board FCB may include an input detection circuit that controls the input sensor ISU.

Although a structure in which the display panel DP of the present disclosure includes the first pads DP-DPD for mounting the driving circuit chip DIC illustrated in FIG. 2A has been described, the present disclosure is not limited thereto. The driving circuit chip DIC (see FIG. 2A) may be mounted on the flexible circuit board FCB, and in this case, the first pads DP-DPD inside the display panel DP may be omitted.

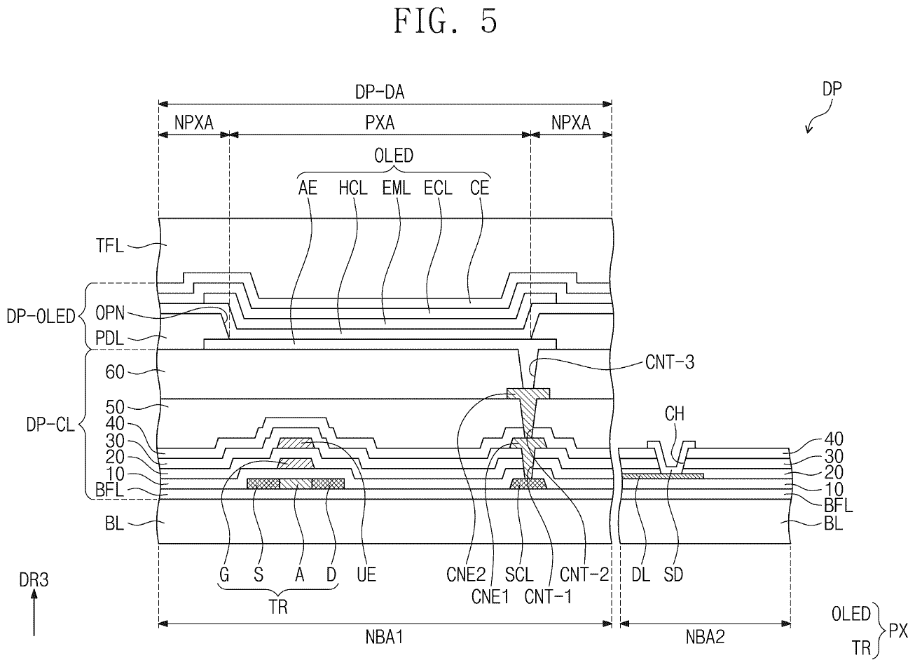

FIG. 5 is a cross-sectional view of the display panel DP according to an embodiment of the present disclosure.

Referring to FIG. 5, the display area DP-DA may include a light emitting area PXA and a non-light emitting area NPXA. Each of the pixels PX may include an organic light emitting diode (OLED) and a pixel driving circuit connected thereto. In detail, the pixel PX may include a transistor TR and the OLED.

FIG. 5 shows one transistor TR as an example, but the present disclosure is not limited thereto. The pixel PX according to one typical embodiment may include seven transistors and at least one capacitor, and the seven transistors and the capacitor may be electrically connected to each other. However, the numbers of transistors and capacitors in the pixel PX are not limited to seven.

The display panel DP may include a plurality of insulating layers, a plurality of semiconductor patterns, a plurality of conductive patterns, a plurality of signal lines, and the like. The insulating layers, a semiconductor layer, and a conductive layer may be formed by coating, deposition, or the like. After formation, each of the insulating layers, the semiconductor layers, and the conductive layers may be selectively patterned using a photolithography method. The semiconductor patterns, the conductive patterns, the signal lines, and the like included in the circuit element layer DP-CL and the display element layer DP-OLED may be formed in this manner.

The base layer BL may include a synthetic resin layer. The base layer BL may have a multi-layered structure. For example, the base layer BL may have a three-layer structure including a synthetic resin layer, an inorganic layer, and a synthetic resin layer. In one particular example, the synthetic resin layer may be a polyimide-based resin layer, but a material of the synthetic resin layer is not particularly limited thereto. In addition, the base layer BL may include a glass substrate, a metal substrate, an organic/inorganic composite material substrate, or the like.

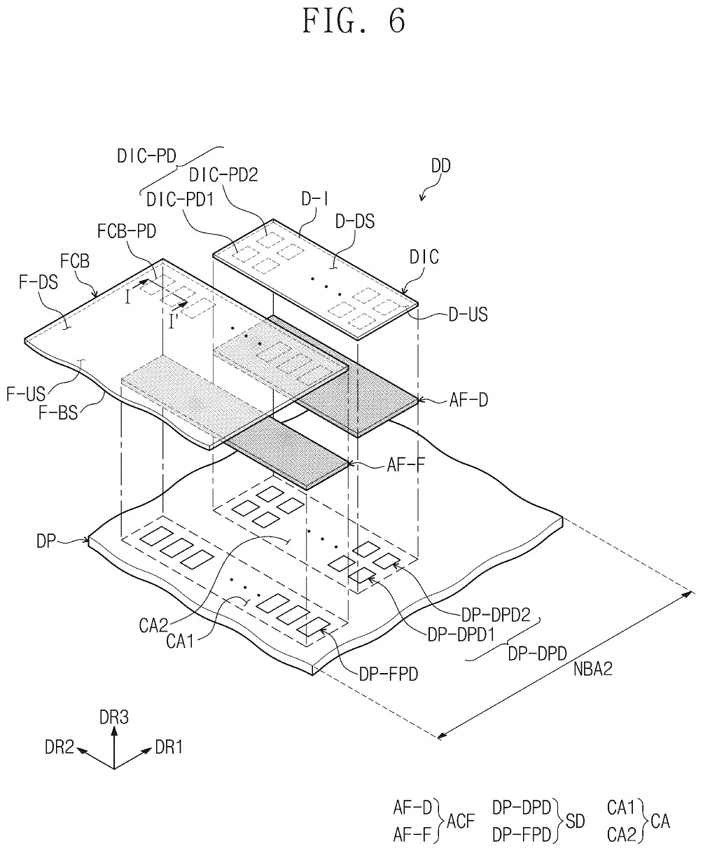

At least one inorganic layer is disposed on an upper surface of the base layer BL. The inorganic layer may be formed in multiple layers. The multi-layered inorganic layers may constitute a barrier layer and/or a buffer layer. FIG. 6 illustrates an embodiment in which the display panel DP includes a buffer layer BFL.

The semiconductor pattern is disposed on the buffer layer BFL. The semiconductor pattern may include polysilicon. However, the present disclosure is not limited thereto, and the semiconductor pattern may include amorphous silicon or metal oxide.

FIG. 5 merely illustrates a portion of the semiconductor pattern, and the semiconductor pattern may be further disposed in another area of the pixel PX or other pixels PX on a plane. The semiconductor pattern may be disposed in a specific rule across the pixels PX. The semiconductor pattern may have different electrical properties depending on whether the semiconductor pattern is doped. The semiconductor pattern may include regions that each include a first area and a second area. The first area may be doped with an N-type dopant or a P-type dopant. For example, a region corresponding to a P-type transistor may include a doped first area doped with the P-type dopant.

A conductivity of the first area may be greater than a conductivity of the second area, and the first area may primarily serve as an electrode or a signal line. The second area has a low doping concentration or may be a non-doped area, and the second area of a semiconductor region may substantially correspond to an active (or a channel) of the transistor corresponding to the region. In other words, a portion of the semiconductor pattern may be an active region or channel of the transistor, another portion of the semiconductor pattern may be a source or a drain of the transistor, and still another portion of the semiconductor pattern may be a connection electrode or a connection signal line.

FIG. 5 shows a portion of the semiconductor pattern that forms a source S, an active region A, a drain D of the transistor TR.

FIG. 5 also illustrates a portion of a connection signal line SCL formed from the semiconductor pattern. In an embodiment, the connection signal line SCL may be electrically connected to a drain of any one of the transistors in the pixel PX.

A first insulating layer 10 is disposed on the buffer layer BFL. The first insulating layer 10 may cover the semiconductor pattern. The first insulating layer 10 may commonly overlap the plurality of pixels PX. A gate G is disposed on the first insulating layer 10. The gate G may be a portion of a metal pattern. The gate G may overlap the active region A. In a process of doping the semiconductor pattern, the gate G (or the metal pattern containing the gate G, may function as a mask.

A second insulating layer 20 that covers the gate G may be disposed on the first insulating layer 10. The second insulating layer 20 may commonly overlap the pixels PX. An upper electrode UE may be disposed on the second insulating layer 20. The upper electrode UE may overlap the gate G of the transistor TR. The upper electrode UE may be a portion of the metal pattern. A portion of the gate G and the upper electrode UE overlapping the gate G may form a capacitor.

A third insulating layer 30 that covers the upper electrode UE may be disposed on the second insulating layer 20. A first connection electrode CNE1 disposed on the third insulating layer 30 may be connected to the connection signal line SCL through a contact hole CNT-1 passing through the first to third insulating layers 10 to 30.

A fourth insulating layer 40 that covers the first connection electrode CNE1 may be disposed on the third insulating layer 30. The first to fourth insulating layers 10 to 40 may be inorganic layers and/or organic layers, and each of the first to fourth insulating layers 10 to 40 may have a single-layer or multi-layer structure.

A fifth insulating layer 50 may be disposed on the fourth insulating layer 40. The fifth insulating layer 50 may be an organic layer. A second connection electrode CNE2 may be disposed on the fifth insulating layer 50. The second connection electrode CNE2 may be connected to the first connection electrode CNEl through a contact hole CNT-2 passing through the fourth insulating layer 40 and the fifth insulating layer 50.

A sixth insulating layer 60 that covers the second connection electrode CNE2 may be disposed on the fifth insulating layer 50. The sixth insulating layer 60 may be an organic layer. A first electrode AE may be disposed on the sixth insulating layer 60. The first electrode AE may be connected to the second connection electrode CNE2 through a contact hole CNT-3 passing through the sixth insulating layer 60.

A pixel opening OPN may be defined in a pixel defining film PDL. The pixel opening OPN when formed in the pixel defining film PDL may expose at least a portion of the first electrode AE. In an embodiment, the light emitting area PXA may correspond to a portion of the first electrode AE that is exposed by the pixel opening OPN.

A hole control layer HCL may be commonly disposed in the light emitting area PXA and the non-light emitting area NPXA. The hole control layer HCL may include a hole transport layer and may further include a hole injection layer. A light emitting layer EML may be disposed on the hole control layer HCL. The light emitting layer EML may be disposed in an area corresponding to the pixel opening OPN. That is, the light emitting layer EML may be separately formed in each pixel. However, the present disclosure is not limited thereto, and the light emitting layer EML may be also commonly formed in the plurality of pixels PX using an open mask.

An electron control layer ECL may be disposed on the light emitting layer EML. The electron control layer ECL may include an electron transport layer and may further include an electron injection layer. The hole control layer HCL and the electron control layer ECL may be commonly formed in the pixels using an open mask. A second electrode CE may be disposed on the electron control layer ECL. The second electrode CE may have an integral or unpatterned shape and may be commonly disposed in the pixels. The upper insulating layer TFL may be disposed on the second electrode CE. The upper insulating layer TFL may include a plurality of thin films.

The buffer layer BFL and the first to fourth insulating layers 10 to 40 may be disposed not only in the first non-bending area NBA1 but also in the second non-bending area NBA2. As shown in FIG. 5, the insulating layer disposed in the first non-bending area NBA1 includes some layers that are also disposed in the second non-bending area NBA2 and includes some layers that do not extend into the second non-bending area NBA2. However, a laminated structure of the insulating layer in the second non-bending area NBA2 is not particularly limited to the embodiment shown in FIG. 5.

Within the second non-bending area NBA2, a portion of the data line DL may be disposed on the first insulating layer 10. Although not shown, within the first non-bending area NBA1, another portion of the data line DL may be disposed on the fifth insulating layer 50. The data line DL may extend from the first non-bending area NBA1 via the bending area BA to the second non-bending area NBA2, and the data line DL may include a plurality of parts arranged on different layers depending on the area.

The display pad SD may be in the second non-bending area NBA2. The display pad SD illustrated in FIG. 5 may be one of the display pads SD illustrated in FIG. 4, for example, one of the first row pads DP-DPD1. The display pad SD may be connected to a portion, for example, a distal end, of the data line DL through a contact hole CH passing through the second to fourth insulating layers 20 to 40.

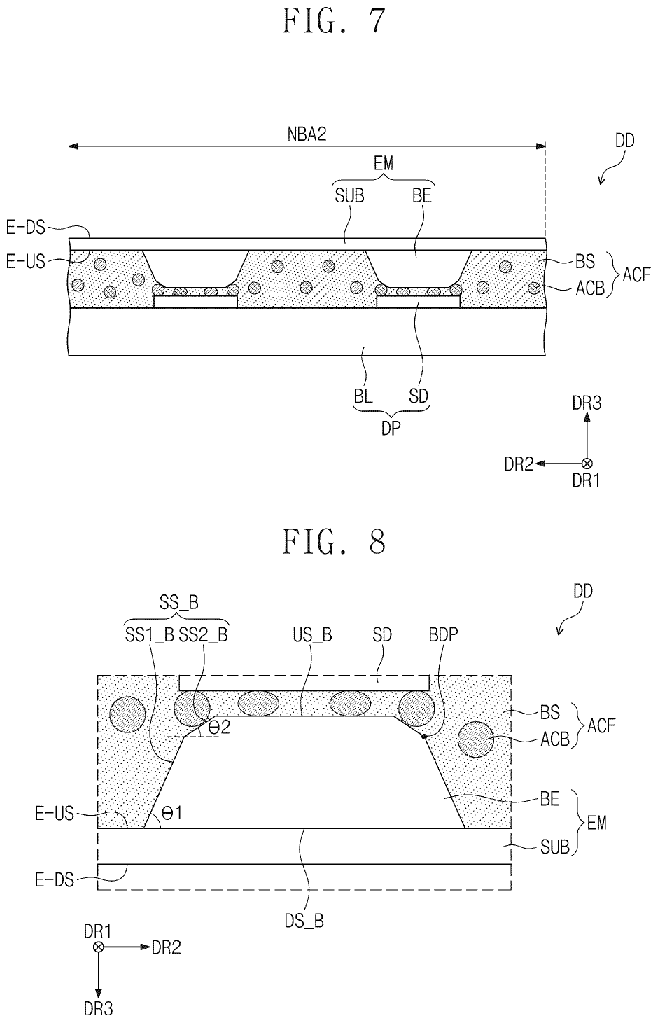

FIG. 6 is an enlarged exploded view of a portion of the display device DD according to an embodiment of the present disclosure. FIG. 7 is an enlarged cross-sectional view of a portion of the display device DD according to an embodiment of the present disclosure. FIGS. 6 and 7, more particularly, are views illustrating a portion of the second non-bending area NBA2 and schematically illustrating some components in the second non-bending area NBA2.

Referring to FIGS. 6 and 7, the display device DD may include the flexible circuit board FCB, the driving circuit chip DIC, a conductive adhesive member ACF, and the display panel DP. For convenience of description, FIG. 6 illustrates that the flexible circuit board FCB, the driving circuit chip DIC, the conductive adhesive member ACF, and the display panel DP are disassembled and spaced apart from each other. However, the display panel DP, a portion of the conductive adhesive member ACF, and the flexible circuit board FCB may be coupled to each other, and the display panel DP, another portion of the conductive adhesive member ACF, and the driving circuit chip DIC may be coupled to each other.

An area of the second non-bending area NBA2, to which the flexible circuit board FCB is bonded may be defined as a first connection area CA1, and an area of the second non-bending area NBA2, to which the driving circuit chip DIC is bonded, may be defined as a second connection area CA2.

The flexible circuit board FCB may include a base layer F-BS and the substrate bump electrodes FCB-PD.

The base layer F-BS may have an upper surface F-US and a lower surface F-DS. In the specification, the upper surface F-US and the lower surface F-DS of the base layer F-BS are defined based on a state in which the flexible circuit board FCB is manufactured. In a state in which the flexible circuit board FCB is attached to the display panel DP, the upper surface F-US of the base layer F-BS may face the display panel DP, and the substrate bump electrodes FCB-PD may be disposed on the upper surface F-US of the base layer F-BS.

The substrate bump electrodes FCB-PD may be linearly arranged along the second direction DR2 on the upper surface F-US of the base layer F-BS. The substrate bump electrodes FCB-PD may be arranged to be spaced apart from each other in the second direction DR2. On a plane, an arrangement of the substrate bump electrodes FCB-PD may be the same as an arrangement of the second pads DP-FPD on the display panel DP. The substrate bump electrodes FCB-PD may have a shape exposed or extending from the upper surface F-US of the base layer F-BS to the outside.

The driving circuit chip DIC may include a driving integrated circuit D-I and chip bump electrodes DIC-PD.

The driving integrated circuit D-I may have an upper surface D-US and a lower surface D-DS. Herein, the upper surface D-US and the lower surface D-DS of the driving integrated circuit D-I are identified based on a state in which the driving circuit chip DIC is manufactured. In a state in which the driving circuit chip DIC is attached to the display panel DP, the upper surface D-US of the driving integrated circuit D-I may face the display panel DP, and the chip bump electrodes DIC-PD may on the upper surface D-US of the driving integrated circuit D-I.

The chip bump electrodes DIC-PD may be arranged an array extending in the first direction DRI and the second direction DR2. The chip bump electrodes DIC-PD may include first row chip bump electrodes DIC-PD1 linearly arranged along the second direction DR2 and second row chip bump electrodes DIC-PD2 spaced apart from the first row chip bump electrodes DIC-PD1 in the first direction DR1 and linearly arranged along the second direction DR2. On a plane, an arrangement of the chip bump electrodes DIC-PD may be the same as an arrangement of the first pads DP-DPD on the display panel DP. The chip bump electrodes DIC-PD may have a shape exposed or extending from the upper surface D-US of the driving integrated circuit D-I toward the display panel DP.

The conductive adhesive member ACF may be disposed between the flexible circuit board FCB and the display panel DP and between the driving circuit chip DIC and the display panel DP. The conductive adhesive member ACF may be an anisotropic conductive film. For example, the conductive adhesive member ACF may include an adhesive resin BS and conductive balls ACB dispersed in the adhesive resin BS as shown in FIG. 7. Alternatively, the conductive adhesive member ACF may be a non-conductive film. For example, the conductive adhesive member ACF may be an adhesive resin that does not contain conductive particles. The conductive adhesive member ACF may include a thermosetting resin.

The conductive adhesive member ACF may include a first conductive adhesive member AF-F disposed between the flexible circuit board FCB and the display panel DP and a second conductive adhesive member AF-D disposed between the driving circuit chip DIC and the display panel DP.

The first conductive adhesive member AF-F may bond the flexible circuit board FCB to the first connection area CAL of the display panel DP. The flexible circuit board FCB may be bonded to the first connection area CA1 by the first conductive adhesive member AF-F. Each of the substrate bump electrodes FCB-PD may be electrically connected to a corresponding second pad DP-FPD among the second pads DP-FPD.

The second conductive adhesive member AF-D may bond the driving circuit chip DIC to the second connection area CA2 of the display panel DP. The driving circuit chip DIC may be bonded to the second connection area CA2 by the second conductive adhesive member AF-D. Each of the chip bump electrodes DIC-PD may be electrically connected to a corresponding first pad DP-DPD among the first pads DP-DPD.

FIG. 7 illustrates a state in which an electronic component EM and the display panel DP are attached through the conductive adhesive member ACF. The electronic component EM may include a substrate SUB having a lower surface E-DS and an upper surface E-US and bump electrodes BE arranged on the upper surface E-US of the substrate SUB. The bump electrodes BE and the display pads SD may be electrically connected through the conductive adhesive member ACF. The electronic component EM of FIG. 7 may be the flexible circuit board FCB or the driving circuit chip DIC of FIG. 6. The display pads SD of FIG. 7 may be the first pads DP-DPD or the second pads DP-FPD of FIG. 6. When the electronic component EM is the flexible circuit board FCB, the bump electrodes BE may be the substrate bump electrodes FCB-PD, the substrate SUB may be the base layer F-BS, and the display pads SD may be the second pads DP-FPD. When the electronic component EM is the driving circuit chip DIC, the bump electrodes BE may be the chip bump electrodes DIC-PD, the substrate SUB may be the driving integrated circuit D-I, and the display pads SD may be the first pads DP-DPD.

The conductive adhesive member ACF may connect each of the bump electrodes BE to a corresponding display pad SD among the display pads SD. The conductive balls ACB may electrically connect the bump electrodes BE to the respective display pads SD. Accordingly, the electronic component EM may be electrically connected to the display panel DP.

In an embodiment, when the electronic component EM and the display panel DP are arranged adjacent to the conductive adhesive member ACF, a near-infrared laser beam may be irradiated in the third direction DR3 through a lower side of the base layer BL of the display panel DP. As the near-infrared laser beam is irradiated on the conductive adhesive member ACF, the conductive adhesive member ACF may be cured. As the conductive adhesive member ACF is cured, the electronic component EM and the display panel DP may be connected and fixed to each other.

FIG. 7 illustrates an example in which the display pads SD are directly on the base layer BL, but at least one insulating layer may be further disposed between the display pads SD and the base layer BL.

FIG. 8 is an enlarged cross-sectional view of a portion of the display device DD according to an embodiment of the present disclosure. FIG. 8 particularly shows an enlarged view of a portion containing one bump electrode BE. For convenience of description, FIG. 8 illustrates a state in which the upper surface E-US of the substrate SUB is disposed on an upper side, the lower surface E-DS is disposed on a lower side, and the bump electrode BE is disposed on the substrate SUB.

Referring to FIG. 8, the bump electrode BE may include an upper surface US_B, a lower surface DS_B opposite thereto, and a side surface SS_B extending from the lower surface DS_B to the upper surface US_B. Herein, the lower surface DS_B of the bump electrode BE may be a surface in contact with the substrate SUB, and the upper surface US_B may be a surface opposite to the lower surface DS_B and facing the display pad SD.

In an embodiment, the side surface SS_B may include a first side surface portion SS1_B and a second side surface portion SS2_B. The first side surface portion SS1_B may be a portion extending from the lower surface DS_B. The second side surface portion SS2_B may be a portion extending from the first side surface portion SS1_B to the upper surface US_B. Herein, the first side surface portion SS1_B and the second side surface portion SS2_B may distinguish portions of the side surface SS_B around a bend, and the first side surface portion SS1_B and the second side surface portion SS2_B may define a bend point BDP in the side surface SS_B.

An inclination θ1 of the first side surface portion SS1_B with respect to the lower surface DS_B and an inclination θ2 of the second side surface portion SS2_B with respect to the lower surface DS_B may be different from each other. In an embodiment, the inclination θ2 of the second side surface portion SS2_B with respect to the lower surface DS_B may be smaller than the inclination θ1 of the first side surface portion SS1_B with respect to the lower surface DS_B. The inclination θ1 of the first side surface portion SS1_B with respect to the lower surface DS_B may mean an average inclination of the entire first side surface portion SS1_B, and the inclination θ2 of the second side surface portion SS2_B with respect to the lower surface DS_B may mean an average inclination of the entire second side surface portion SS2_B.

The second side surface portion SS2_B may be a portion formed or shaped through a secondary etching operation after a primary etching operation is performed to form the bump electrode BE.

An inclination of the entire surface of the side surface SS_B with respect to the lower surface DS_B may be 90 degrees or less. When the inclination of the side surface SS_B with respect to the lower surface DS_B is greater than 90 degrees, a protrusion may be included at a lateral side of the bump electrode BE, but in an embodiment, the bump electrode BE may not include the protrusion formed at the lateral side thereof. In other words, the bump electrode BE may include a portion having a width that narrows and/or a portion having substantially a constant width in a direction from the lower surface DS_B to the upper surface US_B, and the bump electrode BE may not include a portion having a width that widens in the direction from the lower surface DS_B to the upper surface US_B.

The conductive adhesive member ACF may be in contact with the upper surface US_B, the first side surface portion SS1_B, and the second side surface portion SS2_B of the bump electrode BE. In an embodiment, the conductive adhesive member ACF may entirely cover the upper surface US_B, the first side surface portion SS1_B, and the second side surface portion SS2_B of the bump electrode BE.

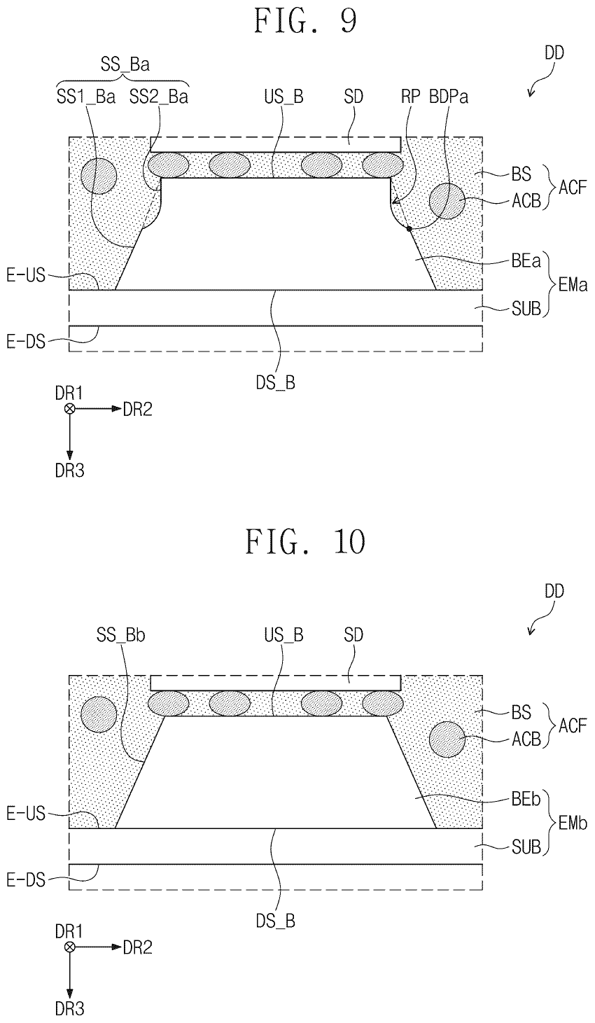

FIG. 9 is an enlarged cross-sectional view of a portion of the display device DD according to an embodiment of the present disclosure. FIG. 9 illustrates a portion corresponding to the cross-sectional view of FIG. 8 and illustrates an embodiment in which the shape of a bump electrode BEa differs from the shape of the bump electrode BE of FIG. 8.

Referring to FIG. 9, the bump electrode Bea may include the upper surface US_B, the lower surface DS_B opposite thereto, and a side surface SS_Ba extending from the lower surface DS_B to the upper surface US_B. In an embodiment, the side surface SS_Ba may include a first side surface portion SS1_Ba and a second side surface portion SS2_Ba. The first side surface portion SS1_Ba and the second side surface portion SS2_Ba may distinguish portions around a bend that is between the lower surface DS_B and the upper surface US_B, and the first side surface portion SS1_Ba and the second side surface portion SS2_Ba may define a bent portion BDPa.

The bump electrode BEa according to an embodiment may have a recessed shape in the second side surface portion SS2_Ba. That is, the second side surface portion SS2_Ba may define a recessed part RP of the bump electrode BEa. For example, the second side surface portion SS2_Ba may be a portion recessed with respect to an extension line of the first side surface portion SS1_Ba.

An inclination of the entire surface of the side surface SS_Ba with respect to the lower surface DS_B may be 90 degrees or less. When the inclination of the side surface SS_Ba with respect to the lower surface DS_B is greater than 90 degrees, a protrusion may be included at a lateral side of the bump electrode BEa, but in the illustrated embodiment, the bump electrode BEa does not include the protrusion formed at the lateral side of the bump electrode BEa. In other words, the bump electrode BEa may include a portion having a width that narrows and/or a portion having substantially a constant width in the direction from the lower surface DS_B to the upper surface US_B. The bump electrode BEa may not include a portion having a width that widens in the direction from the lower surface DS_B to the upper surface US_B.

The second side surface portion SS2_Ba may be a portion formed through a secondary etching operation after a primary etching operation is performed to form the bump electrode BEa. FIG. 9 illustrates the example of a recessed shape in the second side surface portion SS2_Ba, and the recessed shape may change depending on an etching environment during the secondary etching operation.

The conductive adhesive member ACF may be in contact with the upper surface US_B, the first side surface portion SS1_Ba, and the second side surface portion SS2_Ba of the bump electrode BEa. The conductive adhesive member ACF may entirely cover the upper surface US_B, the first side surface portion SS1_Ba, and the second side surface portion SS2_Ba of the bump electrode BEa.

FIG. 10 is an enlarged cross-sectional view of a portion of the display device DD according to an embodiment of the present disclosure. FIG. 10 illustrates an area corresponding to the area shown in the cross-sectional view of FIG. 8 and illustrates an embodiment in which a bump electrode BEb has a shape that differs from the shapes of the bump electrodes BE and BEa shown in FIGS. 8 and 9.

Referring to FIG. 10, the bump electrode BEb may include the upper surface US_B, the lower surface DS_B opposite thereto, and a side surface SS_Bb extending from the lower surface DS_B to the upper surface US_B. A bent portion may not be formed in the side surface SS_Bb according to the embodiment shown in FIG. 10. For example, the side surface SS_Bb may have a substantially constant inclination.

In an embodiment, after the primary etching operation for forming the bump electrode BEb is performed, a protrusion may be formed on a side surface of a preliminary bump electrode. However, the protrusion may then be removed through the secondary etching operation and thus the side surface SS_Bb that does not include the bent portion may be formed.

The conductive adhesive member ACF may be in contact with the upper surface US_B and the side surface SS_Bb of the bump electrode BEb. The conductive adhesive member ACF may entirely cover the upper surface US_B and the side surface SS_Bb of the bump electrode BEb.

According to the embodiments illustrated in FIGS. 8 to 10, no protrusion is included at the lateral side of the bump electrode BE, BEa, or BEb, and thus it is possible to alleviate or prevent formation of a gap between the conductive adhesive members ACF near the side surfaces SS_B, SS_Ba, and SS_Bb of the bump electrodes BE, BEa, and BEb. Accordingly, adhesive defects between the bump electrodes BE, BEa, and BEb and the conductive adhesive member ACF may not occur, and bonding reliability between the display panel DP and the electronic components EM, EMa, and EMb may be improved.

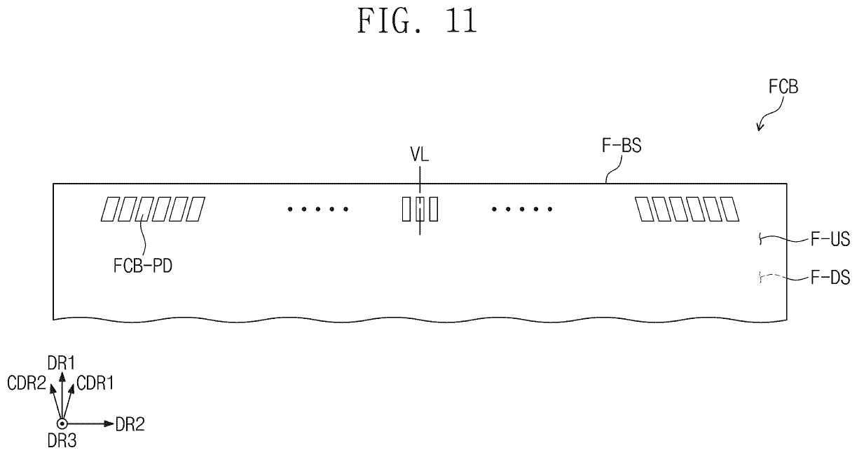

FIG. 11 is a plan view illustrating a portion of a flexible circuit board FCB according to an embodiment of the present disclosure. FIG. 11 particularly illustrates an arrangement of the substrate bump electrodes FCB-PD.

Referring to FIG. 11, the substrate bump electrodes FCB-PD may be linearly arranged along the second direction DR2 and may be spaced apart from each other in the second direction DR2.

Among the substrate bump electrodes FCB-PD, at least some of the substrate bump electrodes arranged on a left side of a reference line VL may have a preset inclination with respect to the reference line VL. Each of the substrate bump electrodes FCB-PD on the left side of the reference line VL may extend in a first diagonal direction CDR1. The first diagonal direction CDR1 may be a direction between the first direction DRI and the second direction DR2 on the plane defined by the first direction DRI and the second direction DR2.

Among the substrate bump electrodes FCB-PD, at least some of the substrate bump electrodes arranged on a right side of the reference line VL may have a preset inclination with respect to the reference line VL. Each of the substrate bump electrodes FCB-PD arranged on the right side of the reference line VL may extend in a second diagonal direction CDR2. The second diagonal direction CDR2 may be a direction at non-zero angles with the first direction DR1, the second direction DR2, and the first diagonal direction CDR1 on the plane defined by the first direction DRI and the second direction DR2.

The substrate bump electrodes FCB-PD on the left side may form an acute clockwise angle with respect to the reference line VL. The substrate bump electrodes FCB-PD on the right side may form an acute counterclockwise angle with respect to the reference line VL.

Although FIG. 11 illustrates only the arrangement of the substrate bump electrodes FCB-PD, the arrangement of the second pads DP-FPD among the display pads SD may be the same. Further, the arrangement of the substrate bump electrodes FCB-PD illustrated in FIG. 11 may be similarly applied to the arrangement of the chip bump electrodes DIC-PD (see FIG. 6).

The arrangements of the substrate bump electrodes FCB-PD and the chip bump electrodes DIC-PD (see FIG. 6) are not limited to the embodiment illustrated in FIG. 11. For example, all of the substrate bump electrodes FCB-PD or all of the chip bump electrodes DIC-PD (see FIG. 6) may extend in the first direction DR1 and may be arranged in the second direction DR2 without being inclined in a diagonal direction.

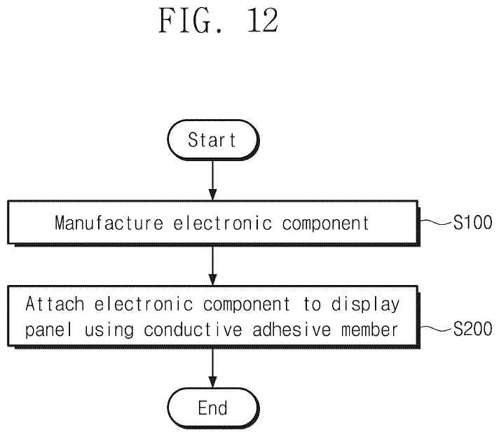

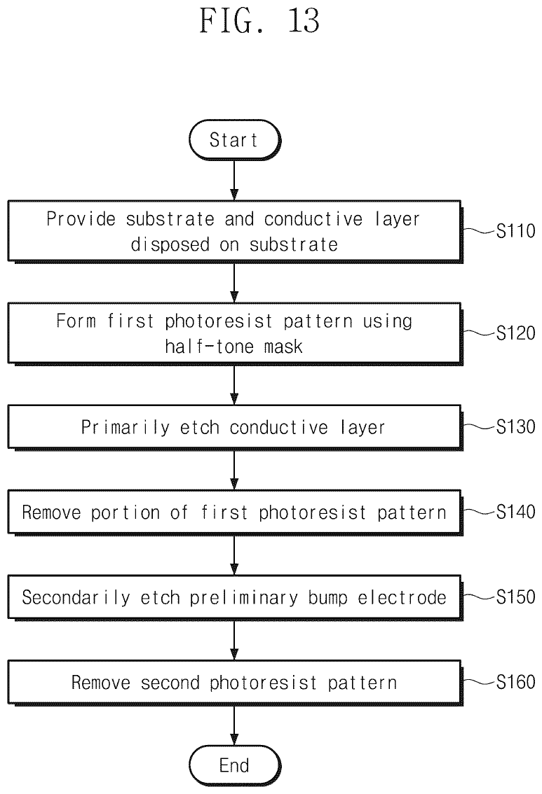

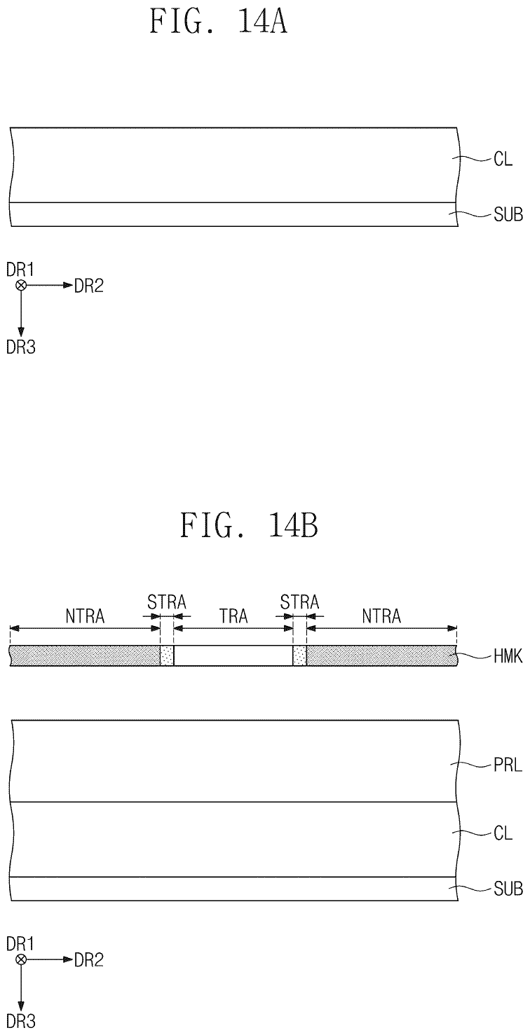

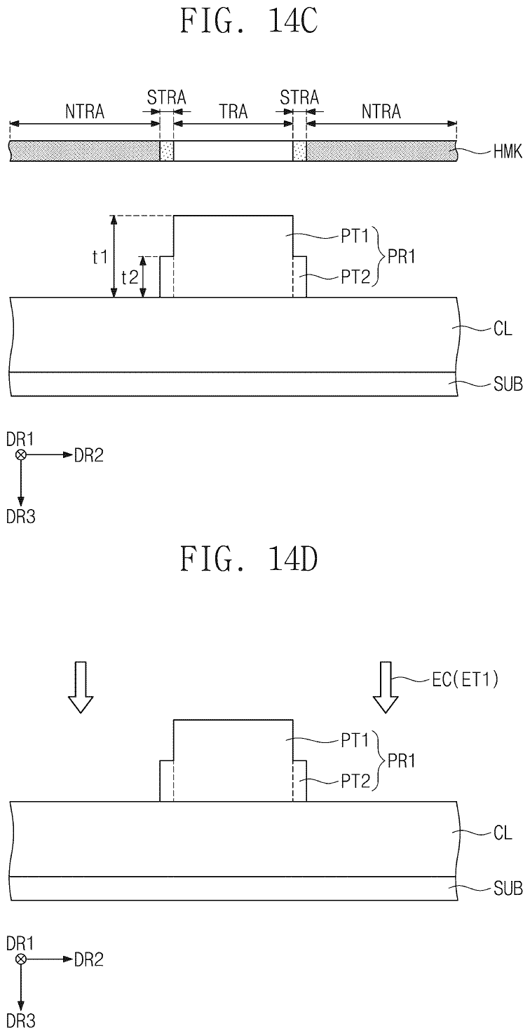

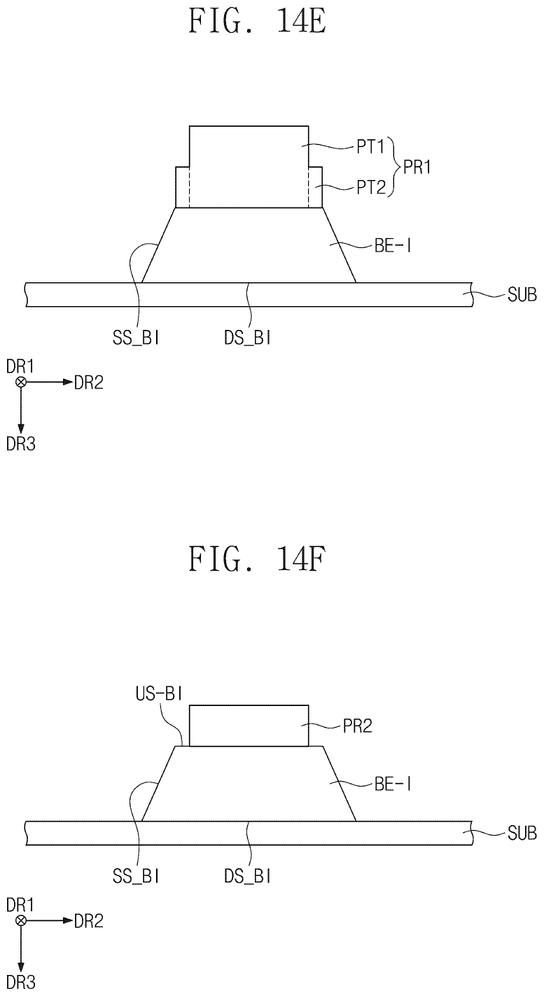

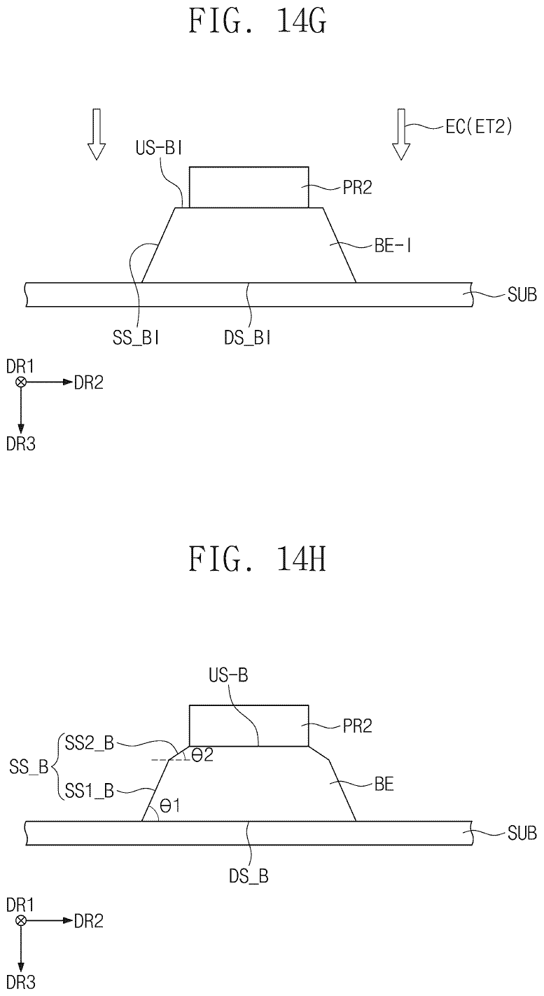

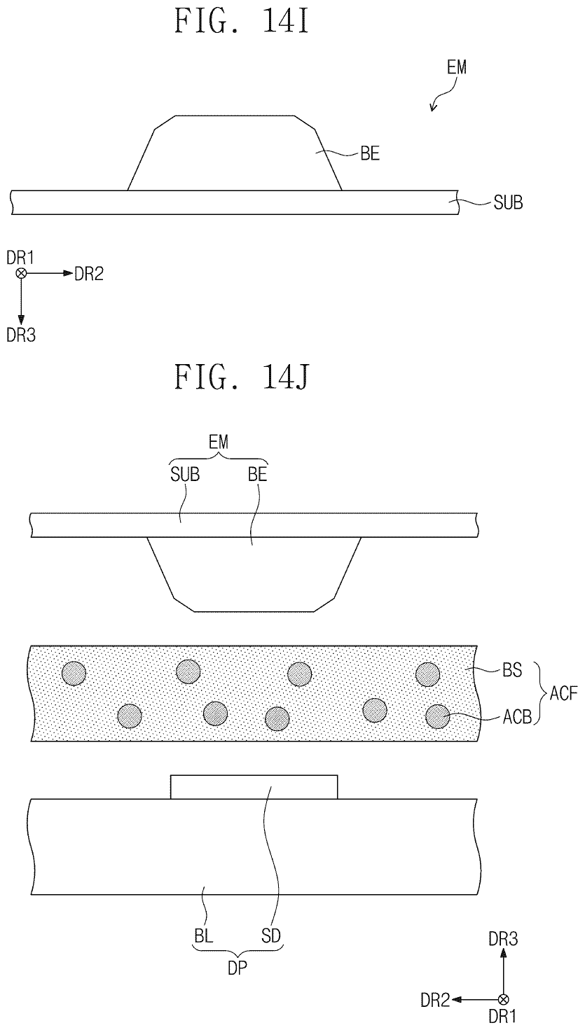

FIGS. 12 and 13 are flowcharts illustrating a method of manufacturing the display device DD (see FIG. 1) according to an embodiment of the present disclosure. FIGS. 14A to 14J illustrate some operations that may be performed during the method of manufacturing the display device DD (see FIG. 1) according to an embodiment of the present disclosure.

A method of manufacturing a display device according to the present disclosure may include an operation of manufacturing an electronic component and an operation of attaching the electronic component to a display panel using a conductive adhesive member. The operation of manufacturing the electronic component may include an operation of providing a substrate and a conductive layer disposed on the substrate, an operation of primary etching the conductive layer to form a preliminary bump electrode, and an operation of secondary etching the preliminary bump electrode to form a bump electrode.

Referring to FIG. 12, according to an embodiment of the present disclosure, the method of manufacturing a display device may include an operation S100 of manufacturing an electronic component and an operation S200 of attaching the electronic component to a display panel using a conductive adhesive member.

Referring to FIG. 13, according to an embodiment of the present disclosure, operation S100 (see FIG. 12) of manufacturing the electronic component may include an operation S110 of providing a substrate and a conductive layer disposed on the substrate, an operation S120 of forming a first photoresist pattern on the conductive layer using a half-tone mask, an operation S130 of primary etching the conductive layer to form a preliminary bump electrode, an operation S140 of removing a portion of the first photoresist pattern to form a second photoresist pattern, an operation S150 of secondary etching the preliminary bump electrode to form a bump electrode, and an operation S160 of removing the second photoresist pattern.

FIGS. 14A to 14I illustrate operation S100 (see FIG. 12) of manufacturing the electronic component according to an embodiment of the present disclosure (see FIG. 12), and FIG. 14J illustrates operation S200 of attaching the electronic component to the display panel using the conductive adhesive member according to an embodiment of the present disclosure (see FIG. 12). FIGS. 14A to 14I illustrate operations corresponding to the flowchart of FIG. 13.

Referring to FIGS. 12, 13, and 14A, the method of manufacturing a display device according to an embodiment may include operation S100 of manufacturing the electronic component EM (see FIG. 141), and operation S100 of manufacturing the electronic component EM (see FIG. 141) according to an embodiment may include operation S110 of providing the substrate SUB and a conductive layer CL disposed on the substrate SUB as shown in FIG. 14A.

Herein, the electronic component EM (see FIG. 141) to be manufactured may correspond to the flexible circuit board FCB (see FIG. 6) or the driving circuit chip DIC (see FIG. 6). When the electronic component EM (see FIG. 14i) to be manufactured is the flexible circuit board FCB (see FIG. 6), the substrate SUB may correspond to the base layer F-BS, and the conductive layer CL may be provided to form the substrate bump electrodes FCB-PD (see FIG. 6). When the electronic component EM (see FIG. 6) is the driving circuit chip DIC (see FIG. 6), the substrate SUB may correspond to the driving integrated circuit D-I (see FIG. 6), and the conductive layer CL may be provided to form the chip bump electrodes DIC-PD (see FIG. 6).

Referring to FIGS. 12, 13, 14B, and 14C, operation S100 of manufacturing the electronic component EM (see FIG. 141) according to an embodiment may include operation S120 of forming a first photoresist pattern PRI on the conductive layer CL.

In an embodiment, operation S120 of forming the first photoresist pattern PR1 may include an operation of forming a photoresist layer PRL on the conductive layer CL, an operation of exposing the photoresist layer PRL using a half-one mask HMK, and an operation of developing the photoresist layer PRL to form the first photoresist pattern PR1.

FIG. 14B illustrates an operation of forming the photoresist layer PRL on the conductive layer CL, disposing a half-tone mask HMK on the photoresist layer PRL, and exposing the photoresist layer PRL using the half-tone mask HMK. FIG. 14C illustrates an operation of developing the photoresist layer PRL having only a partial area that is exposed and then forming the first photoresist pattern PRI from the photoresist layer PRL. For convenience of description, FIG. 14C illustrates together the half-tone mask HMK used in the operation of exposing the photoresist layer PRL.

The half-tone mask HMK may include a transmissive area TRA, a semi-transmissive area STRA, and a non-transmissive area NTRA. The transmissive area TRA may be an area through which all light beams pass. The semi-transmissive area STRA may be an area through which some light passes. The non-transmissive area NTRA may be an area through which no light passes.

When the half-tone mask HMK is used, an area of the photoresist layer PRL, which corresponds to the transmissive area TRA, remains, only a portion of an area of the photoresist layer PRL, which corresponds to the semi-transmissive area STRA, in a thickness direction remains, all an area of the photoresist layer PRL, which corresponds to the non-transmissive area NTRA, in the thickness direction is removed, and thus a portion of the conductive layer CL below the non-transmissive area NTRA may be exposed.

The first photoresist pattern PRI may include a first pattern part PT1 and a second pattern part PT2. The first pattern part PT1 may be a part that entirely remains without being removed in a developing process, and the second pattern part PT2 may be a part that partially remains in the developing process. Thus, a thickness t1 of the first pattern part PT1 may be greater than a thickness t2 of the second pattern part PT2. The first pattern part PT1 and the second pattern part PT2 may form a step. When viewed on a plane, the first pattern part PT1 may be surrounded by the second pattern part PT2.

Referring to FIGS. 12, 13, 14D, and 14E, operation S100 of manufacturing the electronic component EM (see FIG. 141) according to an embodiment may include operation S130 of primary etching the conductive layer CL (or referred to as a first etching operation).

In operation S130 of primary etching the conductive layer CL, the first photoresist pattern PRI may be used as the mask. A portion of the conductive layer CL that the first photoresist patter PRI exposes may be removed, and a preliminary bump electrode BE-I may be formed from the conductive layer CL as shown in FIG. 14E.

In an embodiment, operation S130 of primary etching the conductive layer CL may be performed by wet etching. In operation S130 of primary etching the conductive layer CL, an etchant EC may be used. Operation S130 of primary etching the conductive layer CL may be performed by injecting the etchant EC into the conductive layer CL during a first etching time ET1 as shown in FIG. 14D.

In an embodiment, a side surface SS_BI of the preliminary bump electrode BE-I may be inclined with respect to a lower surface DS_BI. The side surface SS_BI of the preliminary bump electrode BE-I may be inclined at an acute angle with respect to the lower surface DS_BI. However, the present disclosure is not limited thereto, and the side surface

SS_BI of the preliminary bump electrode BE-I may be perpendicular to the lower surface DS_BI.

Referring to FIGS. 12, 13, 14E, and 14F, operation S100 of manufacturing the electronic component EM (see FIG. 141) according to an embodiment may include operation S140 of removing the portion of the first photoresist pattern PR1. Operation S140 of removing the portion of the first photoresist pattern PRI may be performed by a process of ashing the first photoresist pattern PR1.

In operation S140 of removing the portion of the first photoresist pattern PR1, only a portion of the first photoresist pattern PRI may be removed, and a second photoresist pattern PR2 may be formed. The entire second pattern part PT2 of the first photoresist pattern PRI may be removed, and only a portion of the first pattern part PT1, which is thicker than the second pattern part PT2, may be removed. The first pattern part PT1 may be removed in the thickness direction. Accordingly, the second photoresist pattern PR2 may be formed by the remaining first pattern part PT1. The second photoresist pattern PR2 may expose a portion of an upper surface US_BI of the preliminary bump electrode BE-I as shown in FIG. 14F.

Referring to FIGS. 12, 13, 14G, and 14H, operation S100 of manufacturing the electronic component EM (see FIG. 141) according to an embodiment may include operation S150 of secondary etching the preliminary bump electrode BE-I (or referred to as a second etching operation).

In operation S150 of secondary etching the preliminary bump electrode BE-I, the second photoresist pattern PR2 may be used as the mask. A portion of the preliminary bump electrode BE-I may be exposed and removed from the second photoresist pattern PR2, and the bump electrode BE may be formed from the preliminary bump electrode BE-I.

In an embodiment, operation S150 of secondary etching the preliminary bump electrode BE-I may be performed by wet etching. In operation S150 of secondary etching the preliminary bump electrode BE-I, the etchant EC may be used. In operation S150 of secondary etching the preliminary bump electrode BE-I, the same etchant EC as used for operation S130 of primary etching the conductive layer CL may be used. However, the present disclosure is not limited thereto, and an etchant different from that used during operation S130 of primary etching the conductive layer CL may be used.

Operation S150 of secondary etching the preliminary bump electrode BE-I may be performed by injecting the etchant EC into the preliminary bump electrode BE-I for a second etching time ET2. In an embodiment, the second etching time ET2 may be shorter than the first etching time ET1.

In operation S150 of secondary etching the preliminary bump electrode BE-I, an upper portion of the preliminary bump electrode BE-I may be removed, and thus the bump electrode BE including the side surface SS_B having a bent shape may be formed. The bump electrode BE formed in an embodiment may correspond to the bump electrode BE described above in FIG. 8. The side surface SS_B of the bump electrode BE may include the first side surface portion SS1_B and the second side surface portion SS2_B, and the inclination 02 of the second side surface portion SS2_B with respect to the lower surface DS_B may be smaller than the inclination 01 of the first side surface portion SS1_B with respect to the lower surface DS_B.

The first side surface portion SS1_B of the bump electrode BE may have a width that narrows in the direction from the lower surface DS_B to the upper surface US_B, and the second side surface portion SS2_B of the bump electrode BE may also have a width that narrows in the direction from the lower surface DS_B to the upper surface US_B. That is, the bump electrode BE may not include a portion having a width that widens in the direction from the lower surface DS_B to the upper surface US_B.

In an alternative embodiment of the present disclosure, the first side surface portion SS1_B may have a substantially constant width in the direction from the lower surface DS_B to the upper surface US_B.

Referring to FIGS. 12, 13, 14H, and 14I, operation S100 of manufacturing the electronic component EM (see FIG. 141) according to an embodiment may include operation S160 of removing the second photoresist pattern PR2. Operation S160 of removing the second photoresist pattern PR2 may be performed by a process of ashing the second photoresist pattern PR2. Therefore, the electronic component EM including the substrate SUB and the bump electrode BE may be formed as shown in FIG. 14I.

Referring to FIGS. 12 and 14J, the method of manufacturing the display device DD (see FIG. 1) according to an embodiment may include operation S200 of attaching the electronic component EM to the display panel DP using the conductive adhesive member ACF.

Operation S200 of attaching the electronic component EM to the display panel DP using the conductive adhesive member ACF may include an operation of disposing the electronic component EM on the display panel DP so that the display pad SD and the bump electrode BE overlap each other and an operation of heating and pressing the conductive adhesive member ACF between the electronic component EM and the display panel DP.

The electronic component EM may be disposed so that the bump electrode BE and the display pad SD face each other. That is, the electronic component EM may be disposed so that the upper surface E-US of the substrate SUB faces the display panel DP and the lower surface E-DS is positioned on an upper side of the display panel DP facing the substrate SUB.

Thereafter, the display panel DP and the electronic component EM may be attached by pressing any one of the display panel DP and the electronic component EM. In this case, each of the display panel DP and the electronic component EM may contact the conductive adhesive member ACF, and the display pad SD and the bump electrode BE overlapping each other may be electrically connected through the conductive balls ACB.

To attach the display panel DP and the electronic component EM, heat and pressure may be applied using a bonding device. In a heating and pressing process, the adhesive resin BS of the conductive adhesive member ACF may be cured and thus fixed.

After operation S200 of attaching the electronic component EM to the display panel DP, the display device DD (see FIG. 7) including the display panel DP and the electronic component EM electrically connected to each other may be manufactured, and the display panel DP and the electronic component EM attached to each other may have a cross-sectional shape corresponding to FIG. 7.

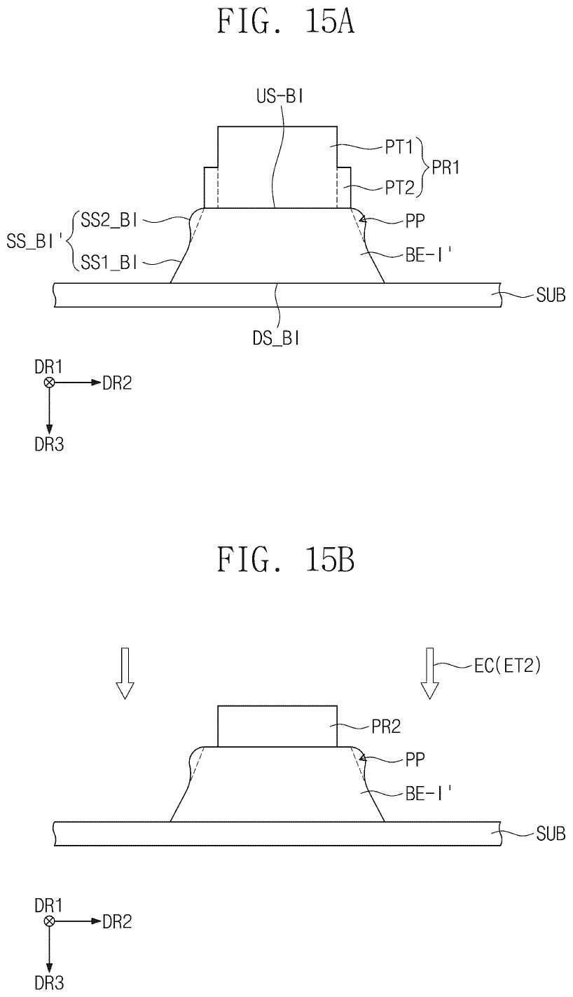

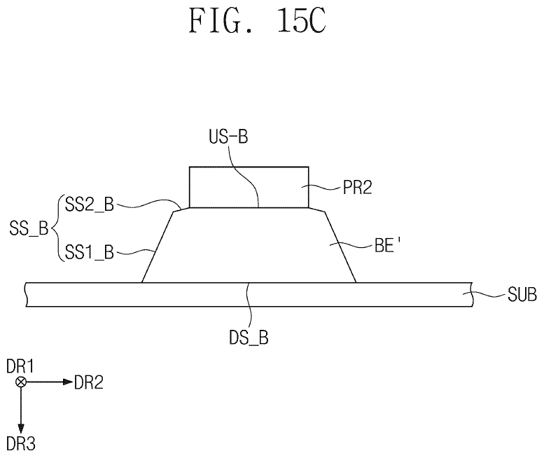

FIGS. 15A to 15C are cross-sectional views of some operations of the method of manufacturing the display device DD (see FIG. 1) according to an embodiment of the present disclosure.

FIG. 15A illustrates an example of a preliminary bump electrode BE-I′ formed in the operation of FIG. 14E. That is, FIG. 15A illustrates an example of the preliminary bump electrode BE-I′ formed through the first etching operation S130 (see FIG. 13).

Referring to FIG. 15A, a side surface SS_BI′ of the preliminary bump electrode BE-I′ according to this embodiment may include a first preliminary side surface portion SS1_BI and a second preliminary side surface portion SS2_BI. The first preliminary side surface portion SS1_BI may be a portion extending from the lower surface DS_BI of the preliminary bump electrode BE-I′, and the second preliminary side surface portion SS2_BI may be a portion extending from the first preliminary side surface portion SS1_BI to the upper surface US_BI of the preliminary bump electrode BE-I′.

The first preliminary side surface portion SS1_BI may have a width that gradually narrows in a direction from the lower surface DS_BI to the upper surface US_BI. At least a portion of the second preliminary side surface portion SS2_BI may have a width that widens in the direction from the lower surface DS_BI to the upper surface US_BI. The second preliminary side surface portion SS2_BI may define a protrusion PP within the preliminary bump electrode BE-I. The protrusion PP may protrude relative to the first preliminary side surface portion SS1_BI of the preliminary bump electrode BE-I in a direction away from the first preliminary side surface portion SS1_BI (e.g., a side surface direction of the preliminary bump electrode BE-I). The protrusion PP may be generated by a process error in the first etching operation S130.

In an embodiment of the present disclosure, the first preliminary side surface portion SS1_BI may have a substantially constant width in the direction from the lower surface DS_BI to the upper surface US_BI.

FIG. 15A exemplarily illustrates that the protrusion PP protrudes outward further than the first photoresist pattern PR1, but the protrusion PP may also overlap the first photoresist pattern PR1.

FIGS. 15B and 15C illustrate cross-sections in operations corresponding to FIGS. 14G and 14H, respectively. That is, FIG. 15B illustrates the second photoresist pattern PR2 formed through operation S140 (see FIG. 13) of removing the portion of the first photoresist pattern PR1, and FIG. 15C illustrates the bump electrode BE′ formed through the second etching operation S150 (see FIG. 13).

Referring to FIGS. 15B and 15C, the protrusion PP of the preliminary bump electrode BE-I′ may be exposed by the second photoresist pattern PR2 after operation S140 of removing the portion of the first photoresist pattern PR1. The protrusion PP may be removed through operation S150 (see FIG. 13) of secondary etching the preliminary bump electrode BE-I′.

Even when the protrusion PP overlaps the first photoresist pattern PR1, the protrusion PP may be exposed by removing the portion of the first photoresist pattern PR1 to form the second photoresist pattern PR2, and thus the protrusion PP may be removed through operation S150 (see FIG. 13) of secondary etching the preliminary bump electrode BE-I′.

The side surface SS_B of the bump electrode BE′ may include the first side surface portion SS1_B and the second side surface portion SS2_B. The protrusion PP formed in the second preliminary side surface portion SS2_BI is removed through the second etching operation S150 (see FIG. 13), and thus the second side surface portion SS2_B of the bump electrode BE′ may have a width that narrows in the direction from the lower surface DS_B to the upper surface US_B. That is, the bump electrode BE′ may not include a portion having a width that widens in the direction from the lower surface DS_B to the upper surface US_B.

FIG. 15C illustrates an example where the side surface SS_B of the bump electrode BE′ includes a bent portion and includes the first side surface portion SS1_B and the second side surface portion SS2_B, but an embodiment is not limited thereto. For example, the bump electrode BE′ may include the side surface SS_B having a substantially constant inclination with no bent portion.

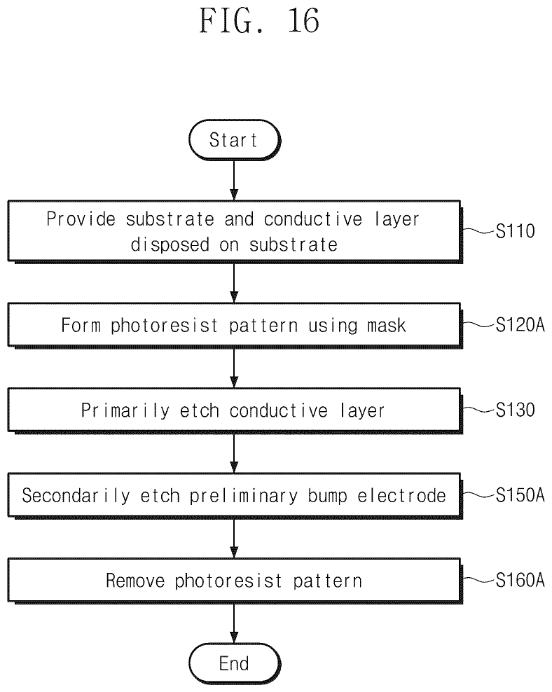

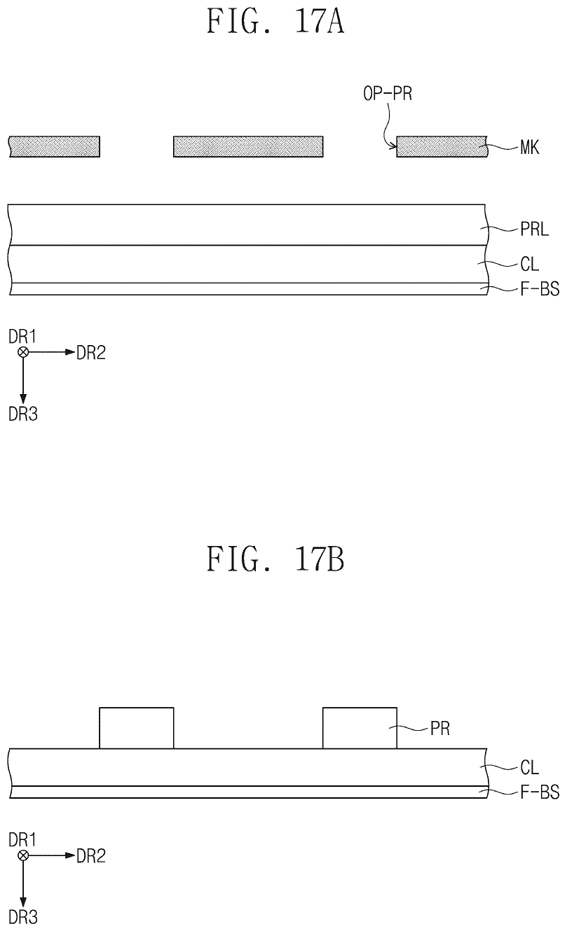

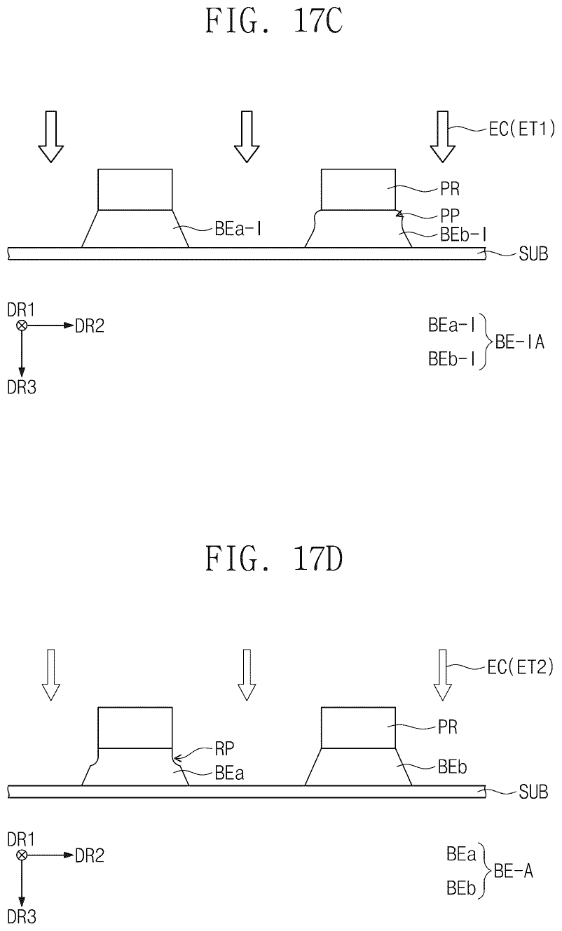

FIG. 16 is a flowchart illustrating some operations of the method of manufacturing the display device DD (see FIG. 1) according to an embodiment of the present disclosure. FIGS. 17A to 17D illustrate some operations of the method of manufacturing the display device DD (see FIG. 1) according to an embodiment of the present disclosure. FIGS. 17A to 17D illustrate a process of forming two bump electrodes.

Referring to FIG. 16, according to an embodiment of the present disclosure, operation S100 (see FIG. 12) of manufacturing an electronic component may include operation S110 of providing the substrate and the conductive layer disposed on the substrate, an operation S120A of forming the photoresist pattern on the conductive layer using a mask, operation S130 of primary etching the conductive layer to form the preliminary bump electrode, an operation S150A of secondary etching the preliminary bump electrode to form the bump electrode, and an operation S160A of removing the photoresist pattern.

Referring to FIGS. 16 and 17A, operation S100 (see FIG. 12) of manufacturing the electronic component EM (see FIG. 7) according to an embodiment may include operation S110 of providing the substrate SUB and the conductive layer CL disposed on the substrate SUB and operation S120A of forming the photoresist pattern PR on the conductive layer CL.

In an embodiment, operation S120A for forming the photoresist patterns PR may include an operation of forming the photoresist layer PRL on the conductive layer CL, an operation of exposing the photoresist layer PRL using a mask MK, and an operation of developing the photoresist layer PRL to form the photoresist patterns PR as shown in FIG. 17B.

Exposure openings OP-PR may be defined in the mask MK. When the photoresist layer PRL is exposed using the mask MK, all areas of the photoresist layer PRL, which corresponds to the exposure openings OP-PR, may be removed in the thickness direction. An area of the photoresist layer PRL, which overlaps the mask MK, may remain.

Each of the photoresist patterns PR in an embodiment may not include a stepped portion as compared to the first photoresist pattern PR1 in an embodiment described above in FIGS. 14A and 14B. That is, each of the photoresist patterns PR may have a substantially constant thickness.

Referring to FIGS. 16, 17B, and 17C, operation S100 (see FIG. 12) of manufacturing the electronic component EM (see FIG. 141) according to an embodiment may include operation S130 of primary etching the conductive layer CL.

In operation S130 of primary etching the conductive layer CL, the photoresist patterns PR may be used as the mask. A portion of the conductive layer CL may be exposed by the photoresist patterns PR and may be removed, and preliminary bump electrodes BE-IA may be formed from the conductive layer CL as shown in FIG. 17C.

In an embodiment, one of the preliminary bump electrodes BE-IA (hereinafter, referred to as a first preliminary bump electrode BEa-I) does not include a bent portion and may have a substantially constant inclination. The other one of the preliminary bump electrodes BE-IA (hereinafter, referred to as a second preliminary bump electrode BEb-I) may include the protrusion PP. That is, a process error may occur in the second preliminary bump electrode BEb-I during the first etching operation S130.

Referring to FIGS, 16, 17C, and 17D, operation S100 (see FIG. 12) of manufacturing the electronic component EM (see FIG. 141) according to an embodiment may include operation S150A of secondary etching the preliminary bump electrodes BE-IA to form bump electrodes BE-A. In an embodiment, after the first etching operation S130, the second etching operation S150A may be performed immediately without the operation of removing the photoresist pattern PR.

In operation S150A of secondary etching the preliminary bump electrode BE-IA according to an embodiment, the photoresist pattern PR may be used as the mask, which is like the first etching operation S130. Accordingly, the operation of removing the portion of the photoresist pattern or the operation of forming the separate photoresist pattern may not be needed or included, and thus a process may be simplified.

When a side surface of the first preliminary bump electrode BEa-I is inclined in the first etching operation S130, the side surface of the first preliminary bump electrode BEa-I may be exposed from the photoresist pattern PR. Further, through the second etching operation S150A, a portion of the first preliminary bump electrode BEa-I, which is exposed from the photoresist pattern PR, may be removed. Accordingly, in the second etching operation S150A, the bump electrode (hereinafter, referred to as a first bump electrode BEa) formed from the first preliminary bump electrode BEa-I may include a recessed portion RP. The first bump electrode BEa formed in an embodiment may correspond to the bump electrode BEa described above in FIG. 9.

In the first etching operation S130, the protrusion PP may be formed in the second preliminary bump electrode BEb-I, and the protrusion PP of the second preliminary bump electrode BEb-I may be exposed from the photoresist pattern PR. Further, through the second etching operation S150A, the protrusion PP of the second preliminary bump electrode BEb-I may be removed. Accordingly, the bump electrode (hereinafter, referred to as a second bump electrode BEb) formed from the second preliminary bump electrode BEb-I may not include the protrusion PP. In an embodiment, a side surface of the second bump electrode BEb may have a substantially constant inclination, and the second bump electrode BEb may correspond to the bump electrode BEb described above in FIG. 10.

Accordingly, according to an embodiment, even when a process error occurs in the first etching process S130, the second etching process S150A is performed to prevent the protrusion from remaining on the final bump electrode BE-A. Each of the bump electrodes BE-A may not include a portion having a width that widens in a direction from a lower surface to an upper surface.

FIG. 17D illustrates an example in which the side surface of the second bump electrode BEb has a substantially constant inclination without a bent portion, but an embodiment is not limited thereto. For example, the side surface of the second bump electrode BEb may also include the recessed portion RP.

Although not illustrated, thereafter, the electronic component EM (see FIG. 7) including the bump electrodes BE-A may be manufactured through operation S160A of removing the photoresist pattern PR.

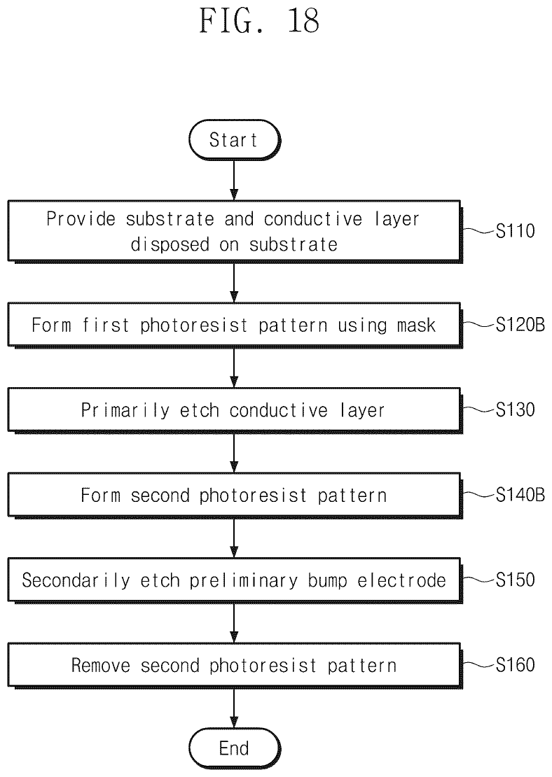

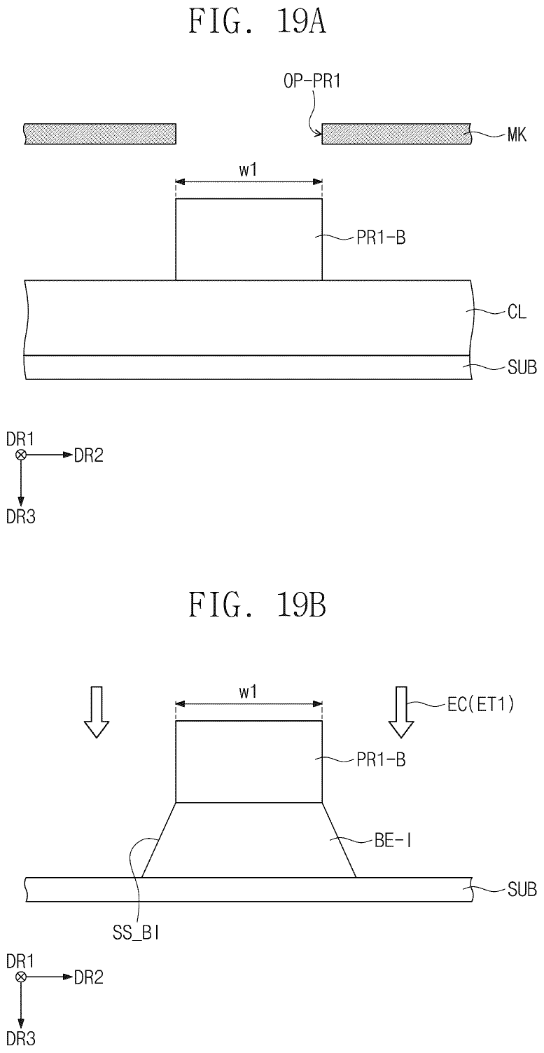

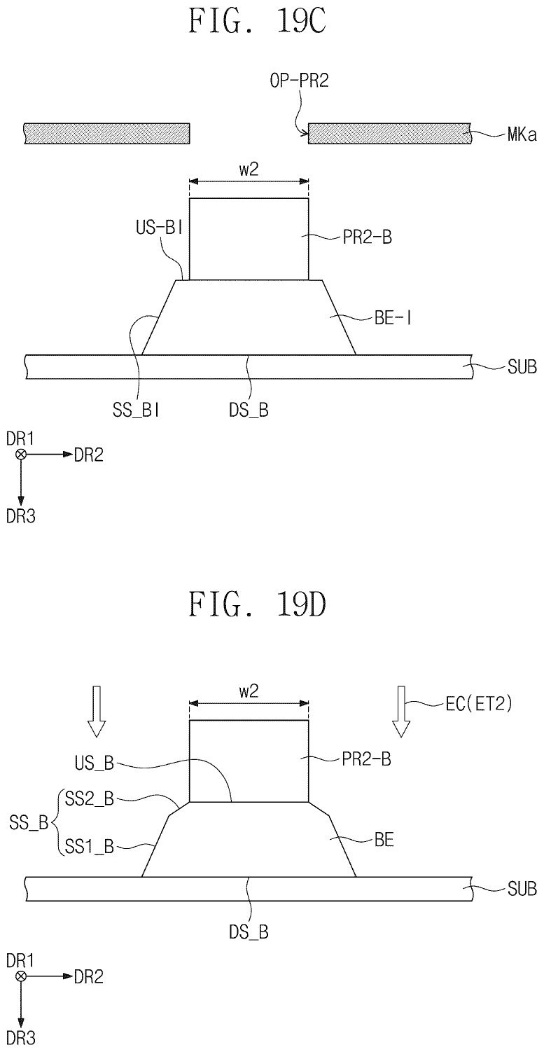

FIG. 18 is a flowchart illustrating some operations of the method of manufacturing the display device DD (see FIG. 1) according to an embodiment of the present disclosure. FIGS. 19A to 19D illustrate some operations of the method of manufacturing the display device DD (see FIG. 1) according to an embodiment of the present disclosure.

Referring to FIG. 18, according to an embodiment of the present disclosure, operation S100 (see FIG. 12) of manufacturing the electronic component (see FIG. 12) may include operation S110 of providing the substrate and the conductive layer disposed on the substrate, an operation S120B of forming the first photoresist pattern on the conductive layer using a mask, operation S130 of primary etching the conductive layer to form the preliminary bump electrode, an operation S140B of forming the second photoresist pattern, operation S150 of secondary etching the preliminary bump electrode to form the bump electrode, and operation S160 of removing the second photoresist pattern.

Referring to FIGS. 18 and 19A, operation S100 (see FIG. 12) of manufacturing the electronic component EM (see FIG. 7) according to an embodiment of the present disclosure may include operation S110 of providing the substrate SUB and the conductive layer CL disposed on the substrate SUB and operation S120B of forming the first photoresist pattern PR1-B on the conductive layer CL using the mask MK.

In operation S120B of forming the first photoresist pattern PR1, the photoresist layer may be exposed using the mask MK (or referred to as a first mask), and a first exposure opening OP-PRI may be defined in the mask MK.

The first photoresist pattern PR1-B may not include a stepped portion, which is unlike the first photoresist pattern PRI in FIG. 14C. That is, a first photoresist pattern PR1-B may have a substantially constant thickness. The first photoresist pattern PR1-B may have a first width w1 in one direction parallel to an upper surface of the conductive layer CL.

Referring to FIGS, 18, 19A, and 19B, operation S100 (see FIG. 12) of manufacturing the electronic component EM (see FIG. 141) according to an embodiment of the present disclosure may include operation S130 of primary etching the conductive layer CL to form the preliminary bump electrode BE-I

In the operation of primary etching the conductive layer CL according to an embodiment, the first photoresist pattern PR1-B may be used as the mask. A portion of the conductive layer CL may be exposed and removed from the first photoresist pattern PR1-B, and a preliminary bump electrode BE-I may be formed from the conductive layer CL.

FIG. 19A illustrates an example in which the preliminary bump electrode BE-I including the side surface SS_BI having a constant inclination is formed through the first etching operation, but some of other preliminary bump electrodes that are not illustrated may include the protrusion PP as described above in FIG. 15B.

Referring to FIGS, 18, 19B, and 19C, operation S100 (see FIG. 12) of manufacturing the electronic component EM (see FIG. 7) according to an embodiment of the present disclosure may include operation S140B of forming a second photoresist pattern PR2-B.

In an embodiment, after the entire first photoresist pattern PR1-B is removed, a photoresist layer may be formed again, the photoresist layer may be exposed using an additional mask MKa (or referred to as a second mask) in which a second exposure opening OP-PR2 is defined, the exposed photoresist layer may be developed, and thus the second photoresist pattern PR2-B may be formed. Alternatively, the photoresist layer may be formed without removing the first photoresist pattern PR1-B.

Although not illustrated, in an embodiment, in the operation of forming the second photoresist pattern PR2-B, an outer portion of the first photoresist pattern PR1-B may be removed, and thus the second photoresist pattern PR2-B may be formed from the first photoresist pattern PR1-B.

The second photoresist pattern PR2-B may have a second width w2 in the one direction that the first photoresist pattern PR1-B had a width w1. The second width w2 may be smaller than the first width w1 of the first photoresist pattern PR1-B. The second photoresist pattern PR2-B may correspond to a shape obtained by removing the outer portion from the first photoresist pattern PR1-B. Accordingly, the second photoresist patter may expose a portion of the upper surface US_BI of the preliminary bump electrode BE-I.

Referring to FIGS, 18, 19C, and 19D, operation S100 (see FIG. 12) of manufacturing the electronic component EM (see FIG. 7) according to an embodiment of the present disclosure may include operation S150 of secondary etching the preliminary bump electrode BE-I.

In operation S150 of secondary etching the preliminary bump electrode BE-I according to an embodiment, the second photoresist pattern PR2-B may be used as the mask. A portion of the preliminary bump electrode BE-I may be exposed and removed from the second photoresist pattern PR2-B, and the bump electrode BE may be formed from the preliminary bump electrode BE-I.

In an embodiment, the description described above in FIG. 14H may be similarly applied. For example, the side surface SS_B of the bump electrode BE may include the first side surface portion SS1_B and the second side surface portion SS2_B, and the inclination of the second side surface portion SS2_B with respect to the lower surface DS_B may be smaller than the inclination of the first side surface portion SS1_B with respect to the lower surface DS_B. Further, the bump electrode BE may not include a portion having a width that widens in the direction from the lower surface DS_B to the upper surface US_B.

Some of the other preliminary bump electrodes that are not illustrated may include protrusions, and in which case, the above description of FIG. 15C may be similarly applied.

Although not illustrated, thereafter, the electronic component EM (see FIG. 7) including the bump electrode BE may be manufactured through the operation of removing the second photoresist pattern PR2-B.

According to an embodiment for the method of manufacturing a display device, which is described above in FIGS. 12 to 19C, two etching processes are performed to form the bump electrode, and thus, protrusions may be prevented from being formed on the finally formed bump electrode. In the first etching operation, even when a protrusion is formed in the preliminary bump electrode due to a process error, the protrusion may be removed through the second etching operation. Therefore, it is possible to alleviate or prevent formation of a gap between the conductive adhesive members near the side surface of the bump electrode. Accordingly, in a process of attaching the display panel and the electronic component and/or a process of using the display device, poor connection between the bump electrode and the display pad may not occur due to poor adhesion between the bump electrode and the conductive adhesive member. The display device having improved bonding reliability between the display panel and electronic components may be manufactured.

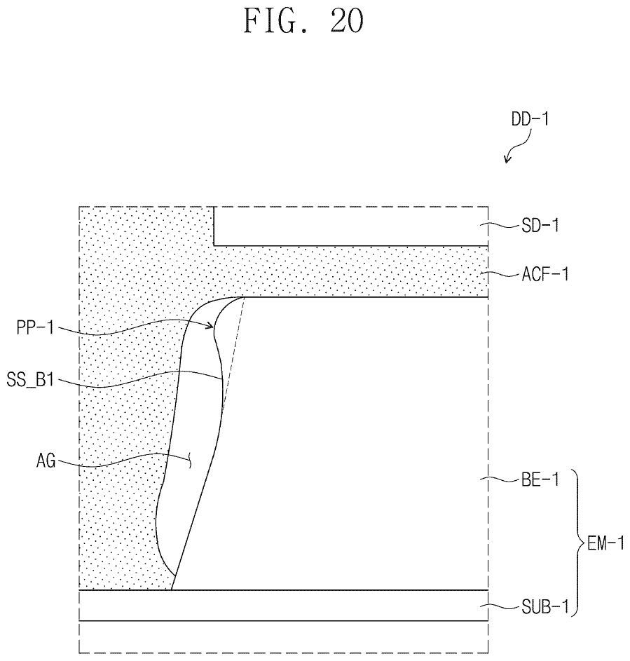

FIG. 20 is an enlarged cross-sectional view of a portion of a display device DD-1 according to a comparative example.

Among the display device DD-1 according to a comparative example, portions of a substrate SUB-1 and a bump electrode BE-1 of an electronic component EM-1, a portion of a display pad SD-1 of a display panel, and a conductive adhesive member ACF-1 in contact with the bump electrode BE-1 and the display pad SD-1 are illustrated. In the specification, the bump electrode BE-1 in the comparative example may be formed from a conductive layer through only one etching operation. The bump electrode BE-1 according to the comparative example may correspond to the preliminary bump electrode BE-I (see FIG. 15A) that is subjected to the first etching operation in an embodiment.

As described above, the protrusion PP (see FIG. 15A) may be formed due to a process error in the first etching operation, and FIG. 20 exemplarily illustrates the bump electrode BE-1 on which a protrusion PP-1 is formed.

When the bump electrode BE-1 on which the protrusion PP-1 is formed is attached to the display panel using the conductive adhesive member ACF-1, a gap AG may be formed near the side surface SS_B1 of the bump electrode BE-1 by the protrusion PP-1 of the bump electrode BE-1. That is, the conductive adhesive member ACF-1 may be spaced apart from at least a portion of the side surface SS_B1 of the bump electrode BE-1, and the at least a portion of the side surface SS_B1 of the bump electrode BE-1 may not be covered by the conductive adhesive member ACF-1.

The conductive adhesive member ACF-1 and the bump electrode BE-1 may not have a sufficient contact area due to the gap AG formed in the manufacturing operation, and thus the display device DD-1 having a poor connection between the bump electrode BE-1 and the display pad may also be formed in the manufacturing operation.

Alternatively, while the display device DD-1 is used after the complete manufacturing, the air gap AG may expand and contract due to a change in a temperature of the electronic component EM-1. In particular, when the air gap AG expands, an adhesive force between the conductive adhesive member ACF-1 and the bump electrode BE-1 is weakened, and thus a contact area between the conductive adhesive member ACF-1 and the bump electrode BE-1 may be reduced. Further, a moisture permeable path may be provided between the conductive adhesive member ACF-1 and the bump electrode BE-1 by the gap AG, and the bump electrode BE-1 may be corroded by moisture introduced through the moisture permeable path. Accordingly, even when a poor connection between the bump electrode BE-1 and the display pad SD-1 does not occur in the manufacturing process, the contact area between the conductive adhesive member ACF-1 and the bump electrode BE-1 shrink while the display device DD-1 is used, and thus a poor connection between the bump electrode BE-1 and the display pad SD-1 may occur during use.

On the other hand, according to the present disclosure, since the protrusion is not included, the gap may not be formed in the attaching operation, and thus a side surface of the bump electrode may be entirely covered. A sufficient contact area between the bump electrode and the conductive adhesive member is provided, and thus a poor connection between the bump electrode and the display pad may not occur. Further, because weakening of an adhesive force due to a temperature change and weakening of an adhesive force due to moisture inflow may not occur, the poor connection may not occur even during use. Thus, bonding reliability and electrical connection reliability between the display panel and the electronic component may be improved.

According to the present disclosure, a bump electrode inside an electronic component may include no protrusion in a side direction. Therefore, it is possible to alleviate or prevent formation of a gap between the bump electrode and a conductive adhesive member, and it is possible to alleviate or prevent a decrease in an adhesive force between the bump electrode and the conductive adhesive member. Thus, bonding reliability between the display panel and the electronic component may be improved.

Although the description has been made above with reference to an embodiment of the present disclosure, it may be understood that those skilled in the art or those having ordinary knowledge in the art may variously modify and changes the present disclosure without departing from the spirit and technical scope of the present disclosure described in the appended claims. Thus, the technical scope of the present disclosure is not limited to the detailed description of the specification but should be defined by the appended claims.

What is claimed is:

1. A method of manufacturing a display device, the method comprising:
manufacturing an electronic component; and
attaching the electronic component to a display panel using a conductive adhesive member,
wherein the manufacturing of the electronic component includes:
providing a substrate and a conductive layer disposed on the substrate;
performing a primary etching of the conductive layer to form a preliminary bump electrode; and
performing a secondary etching of the preliminary bump electrode to form a bump electrode.

2. The method of claim 1, wherein the preliminary bump electrode includes a protrusion protruding in a side direction, and
the protrusion is removed in the secondarily etching of the preliminary bump electrode.

3. The method of claim 1, wherein the primary etching of the conductive layer is performed during a first etching time,
the secondary etching of the preliminary bump electrode is performed during a second etching time, and
the second etching time is shorter than the first etching time.

4. The method of claim 1, wherein the manufacturing of the electronic component further includes:
forming a first photoresist pattern on the conductive layer using a half-tone mask after the providing of the substrate and the conductive layer and before the primary etching of the conductive layer.

5. The method of claim 4, further comprising:
removing a portion of the first photoresist pattern to form a second photoresist pattern after the primary etching of the conductive layer and before the secondary etching of the preliminary bump electrode; and
removing the second photoresist pattern after the secondary etching of the preliminary bump electrode.

6. The method of claim 5, wherein the first photoresist pattern includes a first pattern part and a second pattern part that is thinner than the first pattern part, and in the removing of the portion of the first photoresist pattern, the second pattern part is removed, and an upper portion of the preliminary bump electrode is exposed.

7. The method of claim 1, wherein the manufacturing of the electronic component further includes:
forming a photoresist pattern using a mask in which an exposure opening is defined after the providing of the substrate and the conductive layer and before the primary etching of the conductive layer; and
removing the photoresist pattern after the secondary etching of the preliminary bump electrode.

8. The method of claim 7, wherein in both the primary etching of the conductive layer and the secondary etching of the preliminary bump electrode, the photoresist pattern is used as the mask.

9. The method of claim 1, wherein the manufacturing of the electronic component further includes:
forming a first photoresist pattern using a first mask in which a first exposure opening is defined after the providing of the substrate and the conductive layer and before the primary etching of the conductive layer; and
forming a second photoresist pattern using a second mask in which a second exposure opening is defined after the primary etching of the conductive layer and before the secondary etching of the preliminary bump electrode, and
a width of the second photoresist pattern is smaller than a width of the first photoresist pattern.

10. The method of claim 1, wherein the bump electrode does not include a portion having a width that widens in a direction from a lower surface to an upper surface thereof.

11. The method of claim 1, wherein in the attaching of the electronic component to the display panel, the conductive adhesive member is in contact with an upper surface and a side surface of the bump electrode.

12. The method of claim 1, wherein a side surface of the bump electrode includes:
a first side surface portion extending from a lower surface of the bump electrode; and
a second side surface portion extending from the first side surface portion to an upper surface of the bump electrode and configured to define a bend point with the first side surface portion.

13. The method of claim 1, wherein a side surface of the bump electrode has a substantially constant inclination.

14. The method of claim 1, wherein the electronic component is any one of a flexible circuit board and a driving circuit chip.

15. A display device comprising:
a display panel including a base layer and a display pad disposed on the base layer;
an electronic component disposed on the display panel and including a substrate and a bump electrode disposed under the substrate; and
a conductive adhesive member configured to electrically connect the display panel and the electronic component,
wherein a side surface of the bump electrode includes:
a first side surface portion extending from a lower surface of the bump electrode; and
a second side surface portion extending from the first side surface portion to an upper surface of the bump electrode and configured to define a bend point with the first side surface portion, and
the conductive adhesive member is in contact with the first side surface portion and the second side surface portion.

16. The display device of claim 15, wherein an inclination of the second side surface portion is smaller than an inclination of the first side surface portion.

17. The display device of claim 15, wherein the second side surface portion defines a recessed portion.

18. The display device of claim 15, wherein the bump electrode does not include a portion having a width that widens in a direction from the lower surface to the upper surface thereof.

19. The display device of claim 15, wherein the conductive adhesive member includes an adhesive resin and conductive balls dispersed in the adhesive resin.

20. The display device of claim 15, wherein the electronic component is any one of a flexible circuit board and a driving circuit chip.
